(19) United States
(12) Patent Application Publication
(10) Pub. No.: US 2026/0107705 A1
(43) Pub. Date: Apr. 16, 2026

(54) HIGH THROUGHPUT CONFORMAL THIN FILM DEPOSITION METHOD WITH LOW PRECURSOR CONSUMPTION

(71) Applicant: Eugenus, Inc., San Jose, CA (US)

(72) Inventors: Sang-Hyeob Lee, Fremont, CA (US); Sung-Hoon Jung, Santa Clara, CA (US); Jun Jin Hyon, Kunpo-si (KR); Sung Han Lee, Seongnam-si (KR)

(21) Appl. No.: 19/358,156

(22) Filed: Oct. 14, 2025

Related U.S. Application Data
(60) Provisional application No. 63/708,117, filed on Oct. 16, 2024.

(51) Int. Cl. H10P 14/40; H10P 14/43; H10W 20/00

(52) U.S. Cl. CPC H10P 14/412; H10P 14/432; H10W 20/033

(57) ABSTRACT

The disclosed technology generally relates to forming thin films, and more particularly to high quality, conformal thin films using relatively low amounts of precursor gas, and methods of forming the same. In one aspect, a method of forming a thin film comprises exposing the substrate to one or more vapor deposition cycles in a reaction chamber, wherein exposing the substrate to each vapor deposition cycle comprises exposing the substrate to a first precursor and a second precursor, wherein exposing the substrate to the first precursor and the second precursor is carried out without evacuating to remove a substantial amount of either of the first precursor or the second precursor during and between exposing the substrate to the first precursor and exposing the substrate the second precursor.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims the priority benefit under 35 U.S.C. § 119 (e) to U.S. Provisional Application No. 63/708,117, filed Oct. 16, 2024, entitled “HIGH THROUGHPUT CONFORMAL THIN FILM DEPOSITION METHOD WITH LOW PRECURSOR CONSUMPTION,” the content of which is hereby expressly incorporated by reference in its entirety.

### BACKGROUND

### Field

The disclosed technology generally relates to a method of forming a thin film, and more particularly to forming a conformal thin film layer with low precursor consumption and high throughput.

### Description of the Related Art

As the dimensions of various integrated circuit (IC) structures shrink, thin films are formed on features having increasingly smaller dimensions and complex topologies. For example, as the technology node scales to 10 nm node and beyond, there is a need for thin film layers, e.g., diffusion barriers, that can conformally line high aspect ratio trenches and vias having dimensions as small as few nanometers. While techniques such as physical vapor deposition (PVD) and chemical vapor deposition (CVD) have been used in the IC industry to form thin films for decades, the increased need for conformality of thin films to be deposited in smaller trenches or vias may eventually limit their usage. On the other hand, while atomic layer deposition (ALD) has been demonstrated for conformal deposition of thin films, large amounts of precursor used for forming the film may be wasted to the pump during the deposition process. Thus, there is a need for conformal film deposition methods for forming thin films with high step coverage, while also having low chemical consumption and high throughput, relative to existing methods such as PVD, CVD, or ALD for use in IC fabrication.

### SUMMARY

In one aspect, a method of forming a thin film comprises forming a thin film on a substrate by exposing the substrate to one or more vapor deposition cycles in a reaction chamber. Exposing the substrate to each vapor deposition cycle comprises exposing the substrate to a first precursor, followed by exposing the substrate to a second precursor. Exposing the substrate to the first precursor and the second precursor is carried out without evacuating to substantially remove the first precursor and the second precursor during and between exposing the substrate to the first and second precursors.

In another aspect, a method of forming a thin film comprises forming a thin film on a substrate by exposing the substrate to one or more vapor deposition cycles in a reaction chamber. Exposing the substrate to each vapor deposition cycle comprises exposing the substrate to a first volume of a first precursor and exposing the substrate to a second volume of a second precursor. A ratio of the second volume of the second precursor to the first volume of the first precursor is at least 5. Exposing the substrate to the first and second volumes is carried out without evacuating to substantially remove the first and second volumes during and between exposing the substrate to the first and second volumes.

In another aspect, a method of forming a thin film comprises forming a thin film on a substrate by exposing the substrate to one or more vapor deposition cycles in a reaction chamber comprising a gate valve configured to gate a vacuum pump. Exposing the substrate to each vapor deposition cycle comprises exposing the substrate to a first precursor with the gate valve closed and exposing the substrate to a second precursor with the gate valve closed. Exposing the substrate to the first precursor and the second precursor is carried out without opening the gate valve to substantially remove the first precursor and the second precursor during and between exposing the substrate to the first and second precursors.

In another aspect, a method of forming a thin film comprises forming a thin film on a substrate by exposing the substrate to one or more vapor deposition cycles in a reaction chamber. Exposing the substrate to each vapor deposition cycle comprises exposing the substrate a first precursor, followed by exposing the substrate to a second precursor. One or both of the exposing the substrate to the first precursor and exposing the substrate to the second precursor is followed by waiting for a respective time period of at least 1 second without exposing the substrate to any precursor. Exposing the substrate to the first precursor and the second precursor is carried out without evacuating to substantially remove the first precursor and the second precursor during and between exposing the substrate to the first and second precursors.

In another aspect, a method of forming a thin film comprises forming a thin film on a substrate by exposing the substrate to one or more vapor deposition cycles in a reaction chamber. Exposing the substrate to each vapor deposition cycle comprises exposing the substrate to a first precursor, followed by waiting for a first time period of at least 1 second, followed by exposing the substrate to a second precursor. Exposing the substrate to the first precursor and waiting for the first time period is carried out without evacuating to substantially remove the first precursor.

### BRIEF DESCRIPTION OF THE DRAWINGS

FIG. 1 schematically illustrates the growth of a conformal film using a chemical vapor deposition (CVD) process.

FIG. 2 schematically illustrates the growth of a conformal film using an atomic layer deposition (ALD) process.

FIG. 3 schematically illustrates an example method of forming a conformal film, according to embodiments.

FIG. 4 schematically illustrates an example method of forming a conformal film, according to embodiments.

FIGS. 5A and 5B are flow charts of a deposition method for forming a conformal film by a cyclical vapor deposition process, according to embodiments.

FIG. 6 schematically illustrates an example cyclical vapor deposition method for forming a thin film and a corresponding pressure trace, according to embodiments.

FIG. 7 schematically illustrates an example cyclical vapor deposition method for forming a thin film and a corresponding pressure trace, according to embodiments.

FIG. 8 schematically illustrates an example method of forming a thin film performed within a batch furnace, according to embodiments.

FIG. 9 schematically illustrates an example batch furnace for forming a thin film on a plurality of wafers, according to embodiments.

FIG. 10 illustrates an experimental transmission electron microscopy (TEM) image of a thin film comprising tungsten (W) formed on a patterned substrate using an embodiment of the methods disclosed herein.

FIG. 11 illustrates a secondary ion mass spectroscopy (SIMS) depth profile of a W film similar to that formed on the patterned substrate as shown in FIG. 10, formed on an unpatterned substrate, according to embodiments.

FIGS. 12A-12C illustrate experimental TEM images of a conformal molybdenum (Mo) film formed on high aspect ratio structures by a cyclical vapor deposition method, according to embodiments.

FIGS. 13A-13C illustrate experimental TEM images of a conformal molybdenum (Mo) film formed on high aspect ratio structures by a cyclical vapor deposition method, according to embodiments.

FIG. 14 illustrates experimental TEM images of a conformal molybdenum nitride (MoN) film for lining high aspect ratio structures by a cyclical vapor deposition method, according to embodiments.

FIG. 15 illustrates experimental TEM images of a conformal Mo film for lining high aspect ratio structures by a cyclical vapor deposition method, according to embodiments.

FIG. 16 illustrates experimental TEM images of a conformal Mo film for gap fill of high aspect ratio structures by a cyclical vapor deposition method, according to embodiments.

FIG. 17 schematically illustrates a cross-sectional view of a via lined with film formed by a cyclical vapor deposition method disclosed herein, according to embodiments.

### DETAILED DESCRIPTION

As described above, there is a need in the integrated circuit (IC) industry for methods of forming conformal thin films with reduced cost and high productivity. To address these and other needs, disclosed herein are conformal thin films and cyclical vapor deposition methods of forming the thin films, which display high conformality within high aspect ratio features, while also using substantially less precursor gases than some existing chemical vapor deposition (CVD) and atomic layer deposition (ALD) methods.

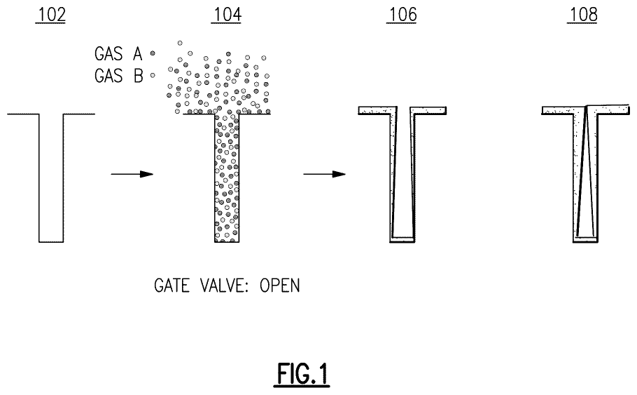

FIG. 1 schematically illustrates the growth of a conformal film using a chemical vapor deposition (CVD) process. FIG. 1, at step 102, illustrates a semiconductor substrate comprising a high aspect ratio (HAR) structure formed therein, illustrating an example surface on which a thin film may be formed. In the illustrated example of the CVD process of FIG. 1 at step 104, both of the gas A and gas B precursors are fed into the chamber holding the semiconductor substrate and corresponding surface. It will be appreciated that different reaction chambers may use different types of valves for controlling the pumping of gas out of the reaction chamber. As used herein, a gate valve refers to any major mechanical valve that is positioned between a reaction chamber and a vacuum pump and capable of evacuating the reaction chamber. For example, a gate valve, as used herein, may refer to a diaphragm valve, a bellows valve, a butterfly valve, etc. The gate valve may be positioned at a relatively high or substantially highest conductance portion between the reaction and the vacuum pump. The gate valve can be controlled to be closed, partially open or fully open to control, e.g., continuously control, the pumping rate. The chamber pressure may be controlled by operating a gate valve of the chamber. Importantly, in the illustrated CVD process at step 104, the gate valve of the chamber is either throttled, or held open, thus allowing a pump to remove at least some of the precursor A or precursor B that is fed into the chamber. In other words, the chamber gate valve may not completely be closed in the CVD process. As the gases A and B and the corresponding precursor molecules reach the semiconductor substrate, they react to form the film X.

The CVD process illustrated herein may be used to form conformal films with limited step coverage and gap fill, as shown in FIG. 1 at steps 106 and 108, respectively. A high step coverage may be desired for barrier metal deposition, e.g., TiN. The gap fill material may comprise W, TiN, Mo, or Cu. In the illustrated CVD process, both of the reactant gases are flowed into the chamber together, sometimes called coflow. In this process, both of the gases are continuously flowed with the chamber gate valve open and react to form the film. However, much of the gas flowing through the chamber during the CVD process does not actually contribute to the film formation. Thus, the amount of precursor gas necessary to form conformal films meeting the step coverage and gap fill requirements may be high in CVD processes. Furthermore, a film formed by CVD may exhibit relatively high impurities affecting film quality and relatively large grain size and/or surface roughness.

Generally, in an ALD process, reactants or precursors, e.g., oxidizing and reducing reactants, are alternatingly introduced into a reaction chamber having disposed therein a substrate. The introduction of one or more reactants or precursors may be in turn be alternated with a purge and/or a pump out process for removing excess reactants or precursors from the reaction chamber. The reactants may be introduced into the reaction chamber under a condition over a suitable period of time such that the surface of the substrate becomes at least partly saturated with the precursors or reactants and/or a reaction product of the reactants. The reactants may be introduced while the reaction chamber is being pumped, e.g., maintained at a fixed chamber pressure, or supplied with fixed flow rates of reactants to maintain target partial pressures of the reactants. After exposure to the reactants for an exposure time, excess or residual precursors or reactants may then be removed, such as by being purged and/or pumped out of the reaction chamber, without introducing additional precursors during pumping. A pump out process may be performed by a suitable vacuum pumping process and a purge step may be performed by introducing a non-reactive or an inert gas, e.g., nitrogen or a noble gas, into the reaction chamber.

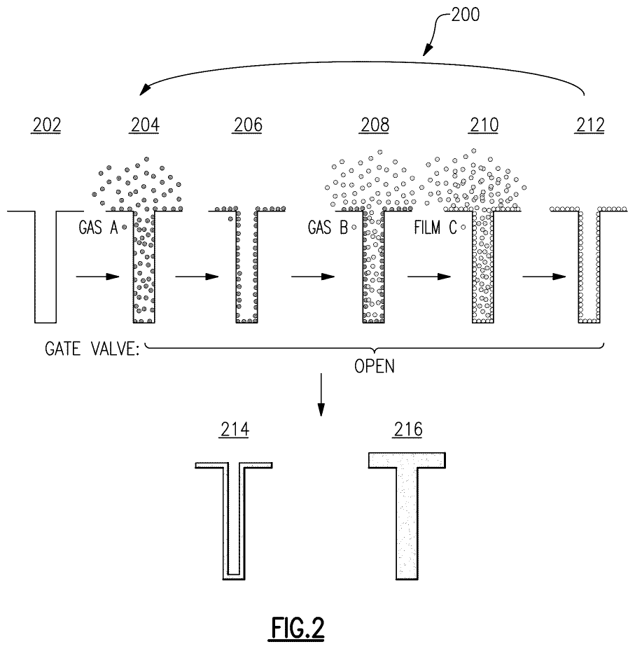

FIG. 2 schematically illustrates the growth of a conformal film using an atomic layer deposition (ALD) process. ALD processes differ from CVD processes in that ALD uses cycles of vapor deposition for forming a thin film. Referring to FIG. 2, at step 202, a semiconductor structure may comprise a high aspect ratio (HAR) structure formed therein, illustrating an example surface on which a thin film may be formed. In the illustrated example of the ALD process, at step 204, each vapor deposition cycle 200 begins with feeding the gas A precursor into the chamber holding the semiconductor structure and corresponding surface. Importantly, in the illustrated ALD process, a gate valve of the chamber is either throttled, or held open, thus allowing a pump to remove at least some of the gas A precursor. In other words, the chamber gate valve may not completely be closed in the ALD process. The gas A precursor is allowed to absorb onto the exposed semiconductor surface. At step 206, once the surface has been saturated with the gas A precursor, the remaining gas A precursor is pumped and purged out of the chamber. During this portion of the vapor deposition cycle 200, most of the gas A precursor that fed into the chamber also ends up pumped out of the chamber. As shown in FIG. 2 at step 206, first flowing the gas A precursor by itself allows for uniform absorption of the precursor onto the wafer surface.

As illustrated in FIG. 2, at step 208, the vapor deposition cycle 200 further comprises feeding the gas B precursor onto the wafer surface to react with the adsorbed gas A to form a monolayer of film X. The gas B precursor reacts with the gas A precursor, only where the gas A precursor exists on the wafer surface. As illustrated in FIG. 2, at step 210, the result is a monolayer of film X. Once the monolayer is formed, at step 212, the remaining unreacted gas B precursor is pumped and purged out of the chamber. Similarly to gas A, most of the gas B precursor fed into the chamber is also pumped out from the chamber. Repeating the vapor deposition cycles 200 for a certain number of times will allow for formation of a desired film thickness, e.g., at 214, or sometimes a complete fill, e.g., at 216.

Similarly to the illustrated CVD process in FIG. 1, the illustrated ALD process of FIG. 2 takes place in a reaction chamber that is open to a vacuum pump. That is, the each reactant may be introduced while the reaction chamber is being pumped, e.g., maintained at a fixed chamber pressure, or supplied with a fixed flow rate of the reactant to maintain a target partial pressure of the reactant. After exposure to the reactant for an exposure time, excess or residual precursors or reactants may then be removed from the reaction chamber. That is, the entire vapor deposition cycle 200 for thin film deposition is performed while the chamber gate valve is at least partially open, or throttled, but not completely closed. Thus, a substantial amount of the gas precursor flowed through the chamber in the ALD process may not actually used for the film formation. Thus, the amount of precursor gas necessary to form conformal films meeting the step coverage and gap fill requirements may also be high in ALD processes.

The inventors have discovered that, when the chamber gate valve is left closed during the majority of a vapor deposition cycle, the amount of gas precursor that may be used to form a highly conformal film can be greatly reduced as compared to traditional ALD processes. Among other reasons, this may be because the first gas precursor has time to spread uniformly throughout the closed reaction chamber. Thus, most of the first gas precursor may be used to react and form layers of the thin film. The inventors have also discovered that the formation of multi-layers using the methods disclosed herein allows for a much higher growth rate than an ALD process. The inventors have further discovered that, after introducing a gas precursor, waiting for a time period without evacuating the reaction chamber may be advantageous to ensure that the precursor is uniformly positioned along the substrate surface and/or uniformly distributed inside the closed reaction chamber.

Disclosed herein are conformal thin films and cyclical vapor deposition methods of forming the thin films, which display high conformality within high aspect ratio features, while also using substantially less precursor gases than some existing chemical vapor deposition (CVD) and atomic layer deposition (ALD) methods. In particular, a method of forming a thin film on a semiconductor substrate comprises exposing the semiconductor substrate in a reaction chamber to one or more cyclical vapor deposition cycles each comprising an exposure to a first precursor and an exposure to a second precursor wherein exposing the substrate to the first and second precursors is carried out without evacuating to substantially remove the first and second precursors during and between exposing the substrate to the first and second precursors. For example, neither of the first precursor nor the second precursor are pumped out of the reaction chamber during the exposures. A reaction chamber may comprise a gate valve connected to a pump for pumping out gases. During each of the vapor deposition cycles of the methods disclosed herein, the gate valve of the reaction chamber may be closed until the end of the vapor deposition cycle when the unreacted precursor is pumped and purged out of the chamber. One or both of the exposure to the first precursor and the exposure to the second precursor may be followed by a wait time without evacuating the reaction chamber to substantially remove the respective precursor. The thin film deposited according to methods disclosed herein advantageously has a high degree of conformality and high growth rate per cycle with relatively low precursor consumption compared to a thin film formed by ALD methods or similar methods without one or both of the wait time and omission of evacuation.

A vapor deposition cycle of the methods disclosed herein may comprise exposing the semiconductor substrate to a first precursor, followed by exposing the semiconductor substrate to a second precursor. The method may additionally comprise waiting for a time period after exposing the semiconductor substrate to the first precursor and before exposing the semiconductor substrate to the second precursor. The first precursor and the second precursor may comprise different gas compounds. The semiconductor substrate may be exposed to a first volume of the first precursor, and exposed to a second volume of the second precursor. The substrate may be exposed to a greater amount of the second precursor than the first precursor. For example, the second volume of the second precursor may be greater than the first volume of the first precursor, e.g., at least 5 times greater than the first volume. The cyclical vapor deposition processes disclosed herein differ from known cyclical vapor deposition processes, such as ALD, in that exposing the substrate to the first and second precursors is carried out without evacuating to substantially remove the first and second precursors during and/or between exposing the substrate to the first and second precursors. Substantially removing a precursor, as used herein, may refer to the pumping the reaction chamber to remove a substantial amount of the precursor. A substantial amount of precursor may be more than about 1-20% of the precursor that is introduced into the reaction chamber in a given vapor deposition cycle. For example, “substantially removing” a precursor may be removing more than 1%, more than 3%, more than 5%, more than 8%, more than 10%, more than 12%, more than 15%, more than 18%, or more than 20% of the introduced precursor from the reaction chamber, or a percentage in a range defined by any of these values.

According to the disclosed technology, by exposing the substrate to the second precursor without having pumped out a substantial amount of the first precursor from the reaction chamber, the film growth may proceed in a multi-layer growth mode, which advantageously can result in a higher growth rate relative to that of deposition methods taking place in an open system. A growth rate may be defined as an increase in thin film thickness as a function of the number of vapor deposition cycles. Since the semiconductor substrate is exposed to the first and second precursor within a closed reaction chamber, a larger amount of the precursor fed into the chamber will be involved in the reaction of film formation compared to existing deposition techniques. A closed reaction chamber may be defined herein as a reaction chamber allowing for the feeding of gas precursor, but not allowing for the pumping out of gas precursor.

In addition, by waiting for a first time period without evacuating after exposing the semiconductor substrate to the first precursor, the first precursor may be uniformly distributed within the chamber and on the substrate before exposure of the semiconductor substrate to the second precursor, which advantageously may allow for step coverage and gap fill comparable or superior to thin films formed from typical ALD processes. As described herein, a step coverage may be defined as a ratio between a thickness of a thin film at a lower or bottom region of a high aspect ratio structure and a thickness of the thin film at an upper or top region of the high aspect ratio structure. By waiting for a second time period without evacuating after exposing the semiconductor substrate to the second precursor, the second precursor may be allowed to adequately diffuse throughout the chamber and react with the first precursor.

It will be appreciated that, during the exposing the substrate to the first precursor, waiting for a first time period, exposing the substrate to the second precursor, and/or waiting for a second time period, inert gas may be flowed into the reaction chamber. The inert gas may be flowed into the reaction chamber through one or more purge gas delivery lines and/or any of the precursor gas delivery lines (e.g., a first precursor gas line and/or a second precursor gas line) which lead into the reaction chamber. For example, during exposing the substrate to the first precursor and/or the second precursor, an inert gas may be flowed into the reaction chamber along with the respective one(s) of the first precursor and the second precursor. The inert gas may serve as a carrier gas, e.g., when a precursor is a liquid precursor. In various embodiments, the inert gas may be flowed simultaneously through one or more gas delivery lines including the first precursor gas line, the second precursor gas line and a continuous purge line. The inventors have discovered that simultaneously flowing may be advantageous under some circumstances, e.g., during any of the above described exposing steps or waiting steps, in preventing backflow of the precursor(s) into the delivery lines, e.g., while the gate valve is closed. In some embodiments, during a waiting step, inert gas may be flowed into the reaction chamber via all of the gas delivery lines of the reaction chamber. The inert gas may include, without limitation, He, Ar and/or N₂ gas.

As a net result, when a vapor deposition cycle is performed in a closed, or substantially, or essentially closed, reaction chamber, the thin film may have a higher growth rate per cycle, while having much lower precursor consumption relative to a thin film layer formed on the same surface using a deposition method with a continuously pumped reaction chamber. Alternatively, or additionally, the thin film may be of high quality with good step coverage and gap fill, in part owing to the first precursor being uniformly distributed throughout the chamber while the chamber is closed to the pump.

As described above, thin film formation plays an important role in integrated circuit (IC) fabrication. While techniques such as physical vapor deposition (PVD), chemical vapor deposition (CVD), and atomic layer deposition (ALD) have been used in the IC industry to deposit thin films, the need for deposition methods for forming films having high conformality with low chemical precursor consumption and high throughput has been increasing.

As described herein, a compound referred to by its constituent elements without specific stoichiometric ratios thereof shall be understood to encompass all possible nonzero concentrations of each element unless explicitly limited. For example, titanium nitride (TiN) shall be understood to encompass all possible stoichiometric and nonstoichiometric compositions of titanium nitride that can be expressed by a general formula TiₓN, where x>0, including TiN, Ti₃N₄, Ti₄N₃, Ti₆N₅, Ti₂N and TiN₂ as well as other non-stoichiometric compositions of Ti and N.

In addition, while ALD may be effective in forming conformal films on surfaces having high aspect ratios, such processes may use high amounts of precursor to achieve a low growth rate per cycle. This is because only a very small amount of precursor saturates the surface to form a mono-layer in each cycle. In these circumstances, the unused precursor is pumped out of the chamber without ever being involved in the reaction forming the thin film. For these reasons, the method disclosed herein may be more advantageous, because the method may use a large amount, e.g., more than about 80%, of a first precursor in forming multiple layers of the thin film in each cycle.

The inventors have recognized that conformal films formed by the methods disclosed herein may be grown within substantially or essentially closed system reaction chamber, wherein the gate valve of the chamber may be substantially or essentially completely closed. In this regard, the inventors have discovered that it may be desirable to grow the films without substantially pumping out any of the precursor, such that most, or substantially or essentially all, of a first precursor may be reacted to form multi-layers of the film on the surface. The inventors have discovered that the gas consumption of a precursor may be significantly lower than that of conventional ALD methods performed under the same process conditions, as described herein without being bound to any theory, in reference to FIGS. 1-3.

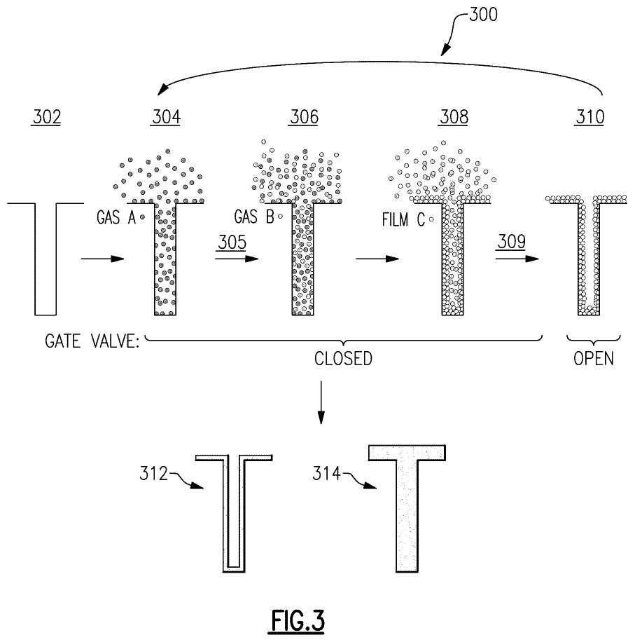

FIG. 3 schematically illustrates the growth of a conformal film according to an embodiment of the methods disclosed herein. The conformal film may be formed by exposing a semiconductor substrate to one or more vapor deposition cycles 300, according to embodiments. Each of the vapor deposition cycles 300 comprises an exposure to a first volume of a first precursor and an exposure to second volume of a second precursor. Referring to FIG. 3, at step 302, a semiconductor structure may comprise a high aspect ratio (HAR) structure formed therein, illustrating an example semiconductor surface on which a thin film may be formed. In the illustrated embodiment of the deposition method, at step 304, each vapor deposition cycle 300 begins with feeding the gas A precursor into the chamber holding the semiconductor structure and corresponding surface. Importantly, in the illustrated deposition process, the volume of gas A is not substantially removed from the chamber by, e.g., keeping a gate valve of the chamber closed such that the gas A precursor is not pumped out of the chamber by a substantial amount after being fed into the chamber. As essentially none of the gas A precursor is pumped out, the gas A precursor is able to uniformly distribute throughout the chamber and onto the semiconductor structure and surface. The vapor deposition cycle 300 may further comprise, at step 305, waiting for a first time period after exposing to allow the gas A precursor to uniformly distribute. The first time period during waiting step 305 may be between 1 second and 1 hour. For example, the first time period may be 1-60 seconds, 60-300 seconds, 300-600 seconds, 600-1200 seconds, 1200-2400 seconds, 2400-3600 seconds, or any time period in a range defined by any of these values. The first time period may vary depending on the process conditions. It will be appreciated that the gate valve may remain closed, e.g., substantially or essentially closed, during the waiting step 305 such that the first precursor is not removed or pumped out of the chamber by a substantial amount.

As illustrated in FIG. 3, once a waiting time period has lapsed for uniform distribution of the gas A precursor, the illustrated vapor deposition cycle 300, at step 306, further comprises feeding the gas B precursor into the reaction chamber without substantially removing the gas B precursor by, e.g., still keeping the reaction chamber closed, e.g., the gate valve is closed. Thus, at step 308, the gas B precursor is allowed to react with the existing gas A precursor within the chamber and on the semiconductor surface to form multi-layers of film X on the surface. The reaction between gas A and gas B may substantially occur on the surface of the substrate, and not in the gas phase. The vapor deposition cycle 300 may further comprise, at step 309, waiting for a second time period to allow for the precursor gases to react. The second time period during waiting step 309 may be between 1 second and 1 hour. For example, the second time period may be 1-60 seconds, 60-300 seconds, 300-600 seconds, 600-1200 seconds, 1200-2400 seconds, 2400-3600 seconds, or any time period in a range defined by any of these values. The second time period may vary depending on process conditions. It will be appreciated that the gate valve may remain closed during the waiting step 309 such that the first precursor or second precursor are not pumped out of the chamber by a substantial amount. Only once the multi-layers are formed, at step 310, the chamber gate valve may be opened to pump and purge a remaining amount of the unreacted gas A precursor, unreacted gas B precursor, and/or by-product gases of the film forming reaction. Repeating the vapor deposition cycles 300 will allow for formation of a desired film thickness capable of meeting step coverage, e.g., film at 312, or gap fill requirements, e.g., film at 314.

Using the methods disclosed herein, the total number of vapor deposition cycles to achieve a desired film thickness may be lower than what would be used during an ALD process under the same process conditions. Furthermore, the amount of gas precursor may be significantly reduced due to less of the precursor being lost to the pump. In some cases, almost all of a volume of the fed gas A precursor, e.g., 60% or greater, 70% or greater, 80% or greater, may be used to form the conformal film in the vapor deposition cycle. By employing the methods according to embodiments, some of the drawbacks of conventional CVD and ALD processes may be avoided, particularly large amounts of precursors.

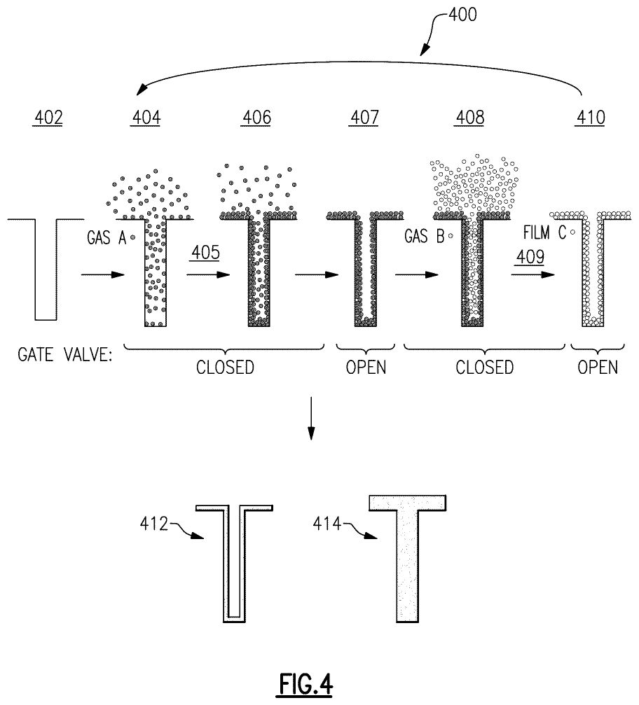

FIG. 4 schematically illustrates the growth of a conformal film according to an embodiment of the methods disclosed herein. The conformal film may be formed by exposing a semiconductor substrate to one or more vapor deposition cycles 400, according to embodiments. Each of the vapor deposition cycles 400 comprises an exposure to a first volume of a first precursor and an exposure to second volume of a second precursor. Referring to FIG. 4, at step 402, a semiconductor structure may comprise a high aspect ratio (HAR) structure formed therein, illustrating an example semiconductor surface on which a thin film may be formed. In the illustrated embodiment of the deposition method, at step 404, each vapor deposition cycle 400 begins with feeding the gas A precursor into the chamber holding the semiconductor structure and corresponding surface. Importantly, in the illustrated deposition process, the volume of gas A is not substantially removed from the chamber by, e.g., keeping a gate valve of the chamber closed such that the gas A precursor is not pumped out of the chamber by a substantial amount immediately after being fed into the chamber. As essentially none of the gas A precursor is pumped out, the gas A precursor is able to uniformly distribute throughout the chamber and onto the semiconductor structure and surface. The vapor deposition cycle 400 may further comprise, at step 405, waiting for a first time period after exposing to allow the gas A precursor to uniformly distribute. The first time period during waiting step 405 may be between 1 second and 1 hour. For example, the first time period may be 1-60 seconds, 60-300 seconds, 300-600 seconds, 600-1200 seconds, 1200-2400 seconds, 2400-3600 seconds, or any time period in a range defined by any of these values. The first time period may vary depending on the process conditions. It will be appreciated that the gate valve may remain closed during the waiting step 405 such that the first precursor is not pumped out of the chamber by a substantial amount.

As illustrated in FIG. 4, once a waiting time period has lapsed for uniform distribution of the gas A precursor, at step 406, the gas A precursor may be adsorbed on the surface of the substrate. The illustrated vapor deposition cycle, at step 407, further comprises evacuating the reaction chamber to remove a substantial amount of the gas A precursor, e.g., more than 20% of the gas A precursor that remains in the reaction chamber without being adsorbed on the substrate. The illustrated vapor deposition cycle 400, at step 408, further comprises feeding the gas B precursor into the reaction chamber without substantially removing the gas B precursor by, e.g., still keeping the reaction chamber closed, e.g., the gate valve is closed. Thus, at step 408, the gas B precursor is allowed to react with the gas A on the semiconductor surface to form a layer of film X on the surface. The vapor deposition cycle 400 may further comprise, at step 409, waiting for a second time period to allow for the precursor gases to react. The second time period during waiting step 409 may be between 1 second and 1 hour. For example, the second time period may be 1-60 seconds, 60-300 seconds, 300-600 seconds, 600-1200 seconds, 1200-2400 seconds, 2400-3600 seconds, or any time in a range defined by any of these values. The second time period may vary depending on process conditions. It will be appreciated that the gate valve may remain closed during the waiting step 409 such that the second precursor is not pumped out of the chamber by a substantial amount during the second time period. Once at least a monolayer of film X is formed, at step 410, the chamber gate valve may be opened to pump and purge a remaining amount of the unreacted gas A and gas B precursor and/or by-product gases of the film forming reaction. Repeating the vapor deposition cycles 400 will allow for formation of a desired film thickness capable of meeting step coverage, e.g., film at 412, or gap fill requirements, e.g., film at 414.

Advantageously, the inventors have discovered that the methods disclosed herein may yield beneficial results when implemented using a batch furnace comprising multiple wafer slots, e.g. 2 to 200 wafer slots. The inventors have recognized that a batch furnace may be the most effective reaction chamber for the disclosed methods because of the high number of wafers per process and the low ratio of chamber cavity volume per wafer. A reaction chamber with a large free volume, e.g. cavities, that are not near a wafer surface can lead to a greater amount of unused first precursor because the first precursor is allowed to uniformly distribute throughout the chamber. Such free volumes can lead to nonuniformities of the precursors due to, e.g., different temperatures and conductance. For example, a single wafer reaction chamber holding a single wafer may have a relatively high cavity volume per wafer inside the chamber relative to a bath reaction chamber. Under embodiments of the methods disclosed herein, much of a gas precursor that uniformly distributes throughout a single wafer reaction chamber may not be used for film formation, and in some cases, may degrade the film formation. Thus, the inventors have discovered that a batch furnace may be particularly adapted for the methods disclosed herein. A batch furnace also allows for high throughput and productivity, and low precursor consumption, using the methods disclosed herein. A batch furnace may have a small chamber cavity volume per wafer held in the chamber, due to the arrangement of the wafers within the chamber, e.g., vertically stacked.

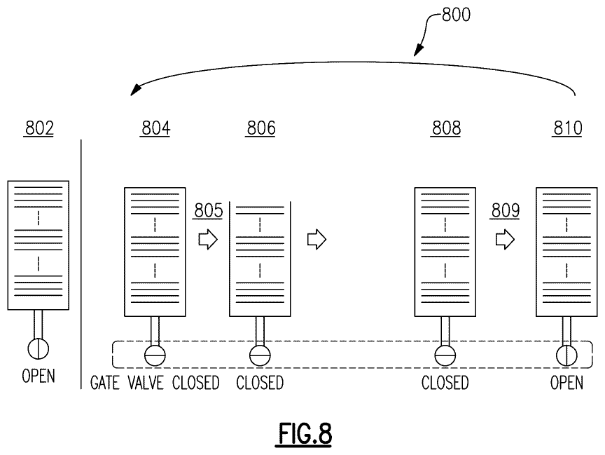

FIG. 8 schematically illustrates an embodiment of the deposition methods disclosed herein performed within a batch furnace. As illustrated, the batch furnace may comprise a reaction chamber holding a plurality of wafers. For example, the batch furnace may comprise 2 to 200 wafer slots. The batch furnace may further comprise a heating source around the periphery of the chamber, such that the heating may be applied evenly to the plurality of wafers. For example, the batch furnace may comprise an induction coil and susceptor heater. The wafers may be stacked, or otherwise arranged such that a wafer surface on which the thin film is to be deposited is exposed. The batch furnace may comprise a gate valve connected to a pump for pumping gas out of the chamber. As illustrated in FIG. 8, at step 802, the reaction chamber may be purged and pumped down to start the process, i.e., the gate valve is opened. Once purged, the wafers in the batch furnace may undergo one or more vapor deposition cycles 800, which may be similar to the process described with respect to FIG. 3 or FIG. 4. The gate valve may be closed such that the precursor gas within the reaction chamber may not be substantially pumped out. The wafers within the reaction chamber may then be exposed to one or more vapor deposition cycles 800. Each vapor deposition cycle 800, at step 804, may begin with feeding a specified volume of the gas A precursor into the reaction chamber while keeping the gate valve closed, e.g., not substantially pumping out gas. Once the specified volume of the gas A precursor has been completely fed, the vapor deposition may comprise, at step 805, waiting for a first time period for the gas A to uniformly distribute throughout the reaction chamber with the gate valve closed. The first time period during waiting step 805 may be between 1 second and 1 hour. For example, the first time period may be 1-60 seconds, 60-300 seconds, 300-600 seconds, 600-1200 seconds, 1200-2400 seconds, 2400-3600 seconds, or any time period in a range defined by any of these values. The first time period may vary depending on process conditions, such as pressure, desired film thickness, temperature, precursor compositions, film thickness uniformity on a wafer, etc.

The vapor deposition cycle 800 illustrated in FIG. 8, at step 806, further comprises feeding the gas B precursor into the reaction chamber while still keeping the gate valve closed. At step 808, the gas B precursor will react with the existing gas A precursor spread uniformly around the reaction chamber to form a film X on the exposed surfaces of each of the plurality of wafers. The vapor deposition cycle 800, at step 809, may comprise waiting for a second time period for the gas B precursor to diffuse throughout the reaction chamber and react with the gas A precursor. The second time period during waiting step 809 may be between 1 second and 1 hour. For example, the second time period may be 1-60 seconds, 60-300 seconds, 300-600 seconds, 600-1200 seconds, 1200-2400 seconds, 2400-3600 seconds, or any time period in a range defined by any of these values. Once the second time period has passed, at step 810, the gate valve may be opened to purge and pump out any unreacted gas A, unreacted gas B precursor, and/or by-product gases of the film forming reaction from the reaction chamber and end the vapor deposition cycle. The second time period during waiting step 809 between introducing gas B into the reaction chamber and opening the gate valve may vary depending on process conditions, such as pressure, desired film thickness, temperature, precursor compositions, film thickness uniformity on a wafer, etc. The vapor deposition cycle 800 may then be repeated until reaching a desired film thickness.

For processing 300 mm wafers, the batch furnace may comprise a total volume greater than 50 L, 100 L, 150 L, 200 L, 250 L, or 300 L, or a volume in a range defined by any of these volumes. For processing smaller or larger wafers, the total volume can be scaled accordingly. The batch furnace may hold a plurality of wafers. For example, the batch furnace may hold anywhere from 2 ato 200 wafers at a time. The batch furnace reaction chamber may comprise a cavity volume per wafer held in the chamber of less than or equal to 2 L. By way of one example, the chamber cavity volume may be 0.6 L per wafer held in the chamber, e.g., when 300 mm wafers are stacked at a pitch of 1 cm.

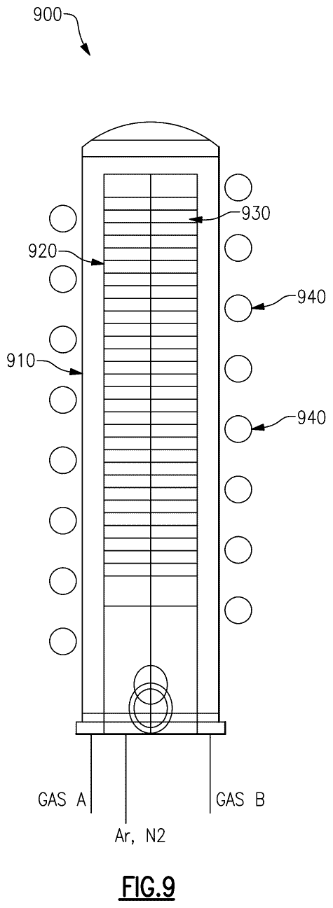

FIG. 9 schematically illustrates an example batch furnace 900 for forming a thin film on a plurality of wafers, according to embodiments. The batch furnace 900 can include a tube 910. The tube 910 may be a hollow vessel designed to contain the materials for processing. The tube 910 may be a cylindrical vessel, as illustrated in FIG. 9. The batch furnace 900 may comprise a wafer boat 920. The wafer boat 920 may comprise a frame with multiple wafer slots or shelves 930 spaced to hold a plurality of wafers. The batch furnace 900 may comprise anywhere from 2 to 200 wafer slots to hold a corresponding number of wafers at a time. As illustrated in FIG. 9, the wafer slots 930 may be spaced to allow the wafers to be stacked in a vertical direction. In some embodiments, the wafers may additionally, or alternatively, be horizontally stacked within the batch furnace 900. The batch furnace 900 may include a heating element 940. As illustrated in FIG. 9, the heating element 940 may comprise an induction coil 940 wrapped around the outside of the tube 910. The batch furnace 900 can include one or more inlets and one or more outlets. The one or more inlets may be used to introduce a first precursor, a second precursor, and/or one or more purge gases. The one or more outlets may be used to pump out any excess first precursor, excess second precursor, or any reaction by-products. The one or more outlets may be controlled by one or more gate valves, as described elsewhere herein.

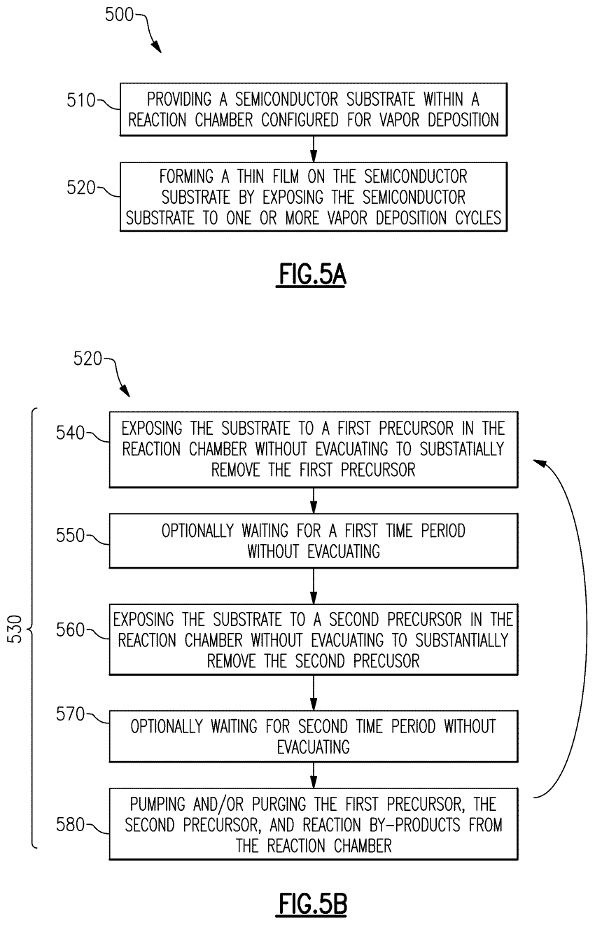

FIG. 5A is a flow chart illustrating a deposition method 500 of forming a conformal film layer by a cyclical vapor deposition process, according to embodiments. The method 500 may comprise providing 510 a substrate with a reaction chamber configured for vapor deposition. The reaction chamber may be a batch furnace for bulk deposition. In some embodiments, without limitation, the substrate may comprise an initial layer, which may be formed in situ, or which may be formed in a separate chamber and then transferred to the reaction chamber for bulk deposition. The initial layer may be formed using the methods disclosed herein, and may comprise, without limitation, any one or more of W, Mo, MON, TiN, TaN, VN, or TiSiN. The method 500 may further comprise forming 520 a thin film on the substrate by exposing the substrate to one or more vapor deposition cycles.

FIG. 5B is a flow chart of forming 520 the thin film of method 500 (FIG. 5A) using one or more vapor deposition cycles 530, according to embodiments. Forming 520 the thin film comprises exposing 540 the substrate to a first precursor without evacuating to substantially remove the first precursor during exposing to the first volume, e.g., by exposing in a closed reaction chamber. A closed reaction chamber may be a chamber that does not allow for any substantial pumping out of gas within the chamber, e.g., by keeping the chamber gate valve closed. Forming 520 the thin film may optionally further comprise waiting 550 for a first time period without evacuating to remove a substantial amount of the first precursor, e.g., for the first precursor to uniformly distribute throughout the closed reaction chamber. The first time period may be between 1 second and 1 hour. For example, the first time period may be 1-60 seconds, 60-300 seconds, 300-600 seconds, 600-1200 seconds, 1200-2400 seconds, 2400-3600 seconds, or any time period in a range defined by any of these values. In some embodiments, after waiting for the first time period without evacuating, the reaction chamber may then be evacuated to remove the first precursor.

Forming 520 the thin film may further comprise exposing 560 the substrate to a second precursor without evacuating to substantially remove the second precursor during exposing to the second precursor, e.g., by exposing in the closed reaction chamber. According to some embodiments, exposing the substrate to both the first precursor and the second precursor is carried out without evacuating to substantially remove the first precursor and the second precursor between exposing the substrate to the first and second volumes, e.g., the gate valve remains closed between exposing the substrate to the first precursor and exposing the substrate to the second precursor. The existing first precursor and the second precursor may react to form a film on an exposed surface of the substrate. Forming 520 the thin film may optionally further comprise waiting 570 for a second time period after exposing the substrate to the second precursor to allow the second precursor to diffuse and allow the precursors to react. The second time period may be between 1 second and 1 hour. For example, the first time period may be 1-60 seconds, 60-300 seconds, 300-600 seconds, 600-1200 seconds, 1200-2400 seconds, 2400-3600 seconds, or any time period in a range defined by any of these values. The additional waiting step 570 may improve uniformity of the thin film. The film may be formed in multiple layers on the surface.

Forming 520 the thin film may further comprise pumping and/or purging 580 the first precursor, second precursor, and reaction by-products from the reaction chamber. In some embodiments, where the reaction chamber was evacuated to remove the first precursor before exposing the substrate to the second precursor, the pumping and/or purging 580 may be removing only the second precursor and reaction by-products. Forming 520 the thin film may further comprise repeating the vapor deposition cycles 530 as described above until a desired film thickness is achieved.

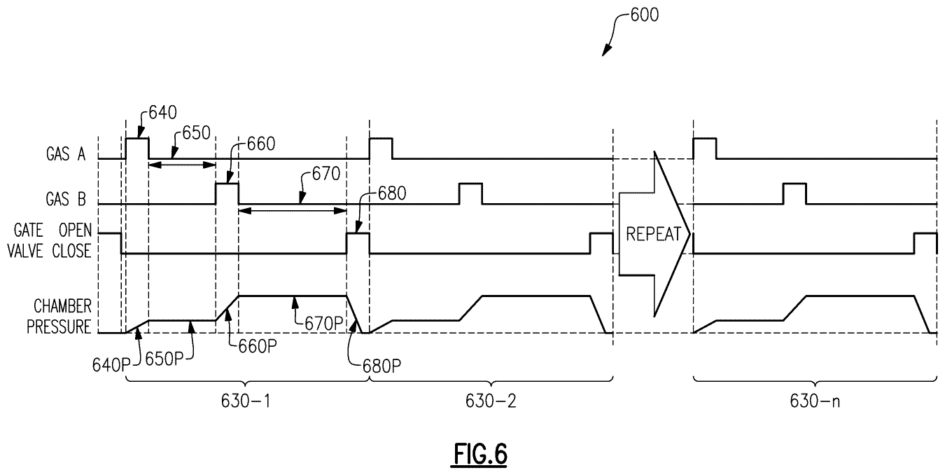

FIG. 6 schematically illustrates a timing sequence of a cyclical vapor deposition method 600 in which a substrate is exposed to a plurality of vapor deposition cycles 630-1, 630-2, . . . , 630-n and a corresponding pressure trace during the vapor deposition cycles, according to various embodiments. FIG. 6 also schematically illustrates the position of the gate valve of a reaction chamber. The substrate is exposed 640 to a first gas precursor, which may then be uniformly distributed throughout the reaction chamber during the waiting 650 for a first time period. The substrate is then exposed 660 to a second gas precursor, which may then uniformly distribute throughout the reaction chamber and react with the first gas precursor during the waiting 670 for a second time period. Referring to FIG. 6, the waiting 650 for a first time period may be shorter than the waiting 670 for a second time period. Embodiments are not so limited, however, and in some embodiments, waiting 650 may be longer than waiting 670 for a second time period. Any of the excess first precursor, excess second precursor, or reaction by-products may be pumped and/or purged 680 from the reaction chamber. The pumping and/or purging 680 may also be referred to herein as evacuating the reaction chamber. Referring to FIG. 6, the gate valve is closed during the exposing 640, waiting 650, exposing 660, and waiting 670, and is opened during the pumping and/or purging 680.

Referring to FIG. 6, in some embodiments, the waiting 650 for the first time period and/or waiting 670 for the second time period may comprise waiting without feeding any gas into the reaction chamber. However, in some embodiments, the waiting 650 for a first time period and/or waiting 670 for a second time period may comprise waiting while feeding only an inert gas. The feeding of the inert gas may maintain a pressure of the reaction chamber at a relatively constant level and/or increase the pressure during the waiting 650 for a first time period and/or waiting 670 for a second time period. In some embodiments, an inert gas may be fed into the reaction chamber along with a respective precursor during the exposure 640 to the first precursor and/or the exposure 660 to the second precursor.

As schematically depicted in FIG. 6, each of the exposure or exposing 640 to the first precursor, waiting 650 for a first time period, exposure or exposing 660 to the second precursor, waiting 670 for a second time period, and pumping and/or purging 680 may have a corresponding pressure regime. For example, the exposure 640 to the first precursor and the exposure 660 to the second precursor may correspond to first and second pressure rise regimes 640P and 660P, respectively. Referring to FIG. 6, it may be appreciated that, until the pumping and/or purging step 680, the chamber pressure may not substantially decrease during each of the vapor deposition cycles 630. The first pressure rise regime 640P may cause the chamber pressure to increase from an initial pressure to a first pressure. The chamber pressure may increase relatively to the amount of respective first precursor being introduced into the reaction chamber. It will be appreciated that where inert gas is fed or present during the exposure 640 to the first precursor, the first pressure may be greater than the partial pressure of the first precursor. In some embodiments, where no inert gas is fed during the exposing 640 to the first precursor, the first pressure may correspond to the pressure of the first precursor. The first pressure rise regime 640P may be followed by a first waiting pressure regime 650P. During the first waiting pressure regime 650P, the chamber pressure may be relatively constant and maintained at the first pressure. In some embodiments, where an inert gas is fed into the reaction chamber during the waiting 650, the chamber pressure may increase relatively to the amount of inert gas fed into the chamber.

Still referring to FIG. 6, the exposure 660 to the second precursor may correspond to a second pressure rise regime 660P. The second pressure rise regime 660P may cause the chamber pressure to increase from the first pressure to a second pressure. The chamber pressure may increase relatively to the amount of respective second precursor being introduced into the reaction chamber. As shown in FIG. 6, the chamber pressure increases by a greater amount during the second pressure rise regime 660P than during the first pressure rise regime 660P, indicating that a greater amount of second precursor was fed into the chamber. It will be appreciated that where inert gas is fed or present during the exposing 660 to the second precursor, the first pressure may correspond to the partial pressure of the second precursor. In some embodiments, where no inert gas is fed during the exposing 660 to the second precursor, the increase in pressure during the second pressure rise regime 660P may correspond to a partial pressure of the second precursor. The second pressure rise regime 660P may be followed by a second waiting pressure regime 670P. During the second waiting pressure regime 670P, the chamber pressure may be relatively constant and maintained at the second pressure. In some embodiments, where an inert gas is fed into the reaction chamber during the waiting 670, the chamber pressure may increase relatively to the amount of inert gas fed into the chamber.

Referring to FIG. 6, after waiting 670 for the second time period, the reaction chamber may be pumped and/or purged 680. The pumping and/or purging 680 may correspond to a pressure fall regime 680P. As shown in FIG. 6, during the pressure fall regime 680P, the chamber pressure may fall from the second pressure back to the initial pressure, such that the vapor deposition cycle 630 may be repeated with a substantially similar chamber pressure regime. The chamber pressure falling back to the initial pressure corresponds to the gate valve being opened during the pumping and/or purging 680, allowing the gas within the chamber to be evacuated.

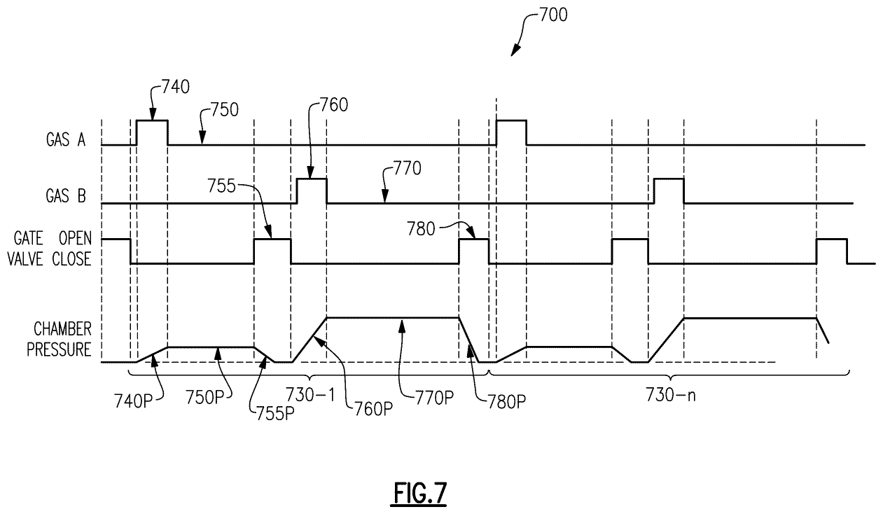

FIG. 7 schematically illustrates an example cyclical vapor deposition method 700 in which a substrate is exposed to a plurality of vapor deposition cycles 730-1, . . . , 730-n and a corresponding pressure trace during the vapor deposition cycles, according to various embodiments. FIG. 7 also schematically illustrates the position of the gate valve of a reaction chamber. The substrate is exposed 740 to a first gas precursor, which may then be uniformly distributed throughout the reaction chamber during the waiting 750 for a first time period. In some embodiments, waiting 750 may include feeding only inert gas into the chamber. Unlike the method described above with respect to FIG. 6, after the waiting 750, the reaction chamber may undergo pumping and/or purging 755, e.g., evacuating, to remove a substantial amount of the first precursor from the reaction chamber. That is, in some embodiments, some of the first precursor may still remain in the reaction chamber after the pumping and/or purging 755. The substrate is then exposed 760 to a second gas precursor, which may then uniformly distribute throughout the reaction chamber and react with the first gas precursor during the waiting 770 for a second time period. In some embodiments, waiting 770 may include feeding only inert gas into the chamber. Referring to FIG. 7, the waiting 750 for a first time period may be shorter than the waiting 770 for a second time period, however, in some embodiments, waiting 750 may be longer than waiting 770 for a second time period. Any of the excess first precursor, excess second precursor, or reaction by-products may be pumped and/or purged 780 from the reaction chamber. The pumping and/or purging 780 may also be referred to herein as evacuating the reaction chamber. Referring to FIG. 7, the gate valve is closed during the exposing 740, waiting 750, exposing 760, and waiting 770, and is opened only during the pumping and/or purging 755 and pumping and/or purging 780.

As schematically depicted in FIG. 7, each of the exposure or exposing 740 to the first precursor, waiting 750 for a first time period, pumping and/or purging 755, exposure or exposing 760 to the second precursor, waiting 770 for a second time period, and pumping and/or purging 780 may have a corresponding pressure regime. For example, the exposure 740 to the first precursor may correspond to a first pressure rise regimes 740P. The first pressure rise regime 740P may cause the chamber pressure to increase from an initial pressure to a first pressure. The chamber pressure may increase relatively to the amount of respective first precursor being introduced into the reaction chamber. In some embodiments, where no inert gas is fed during the exposing 740 to the first precursor, the first pressure may correspond to a pressure of the first precursor. The first pressure rise regime 740P may be followed by a first waiting pressure regime 750P. During the first waiting pressure regime 750P, the chamber pressure may be relatively constant and maintained at the first pressure. In some embodiments, where an inert gas is fed into the reaction chamber during the waiting 750, the chamber pressure may increase corresponding to the amount of inert gas fed into the chamber. Unlike the method illustrated with respect to FIG. 6, the first waiting pressure regime 750P may be followed by a first pressure fall regime 755P corresponding to the pumping and/or purging 755 of the reaction chamber to remove a substantial amount of the first precursor. For example, if essentially all of the first precursor is removed, the chamber pressure may be reset to the initial pressure during the first pressure fall regime 755P. The first pressure fall regime 755P may correspond with the gate valve being open during the pumping and/or purging 755.

Still referring to FIG. 7, the exposure 760 to the second precursor may correspond to a second pressure rise regime 760P. The second pressure rise regime 760P may cause the chamber pressure to increase to a second pressure, which may be different than the first pressure. For example, as shown in FIG. 7, the second pressure rise regime 760P may be an increase from the initial pressure to a second pressure greater than the first pressure. Embodiments are not so limited, however, and in some embodiments, the second pressure may be lower than the first pressure. The chamber pressure may increase relatively to the amount of respective second precursor being introduced into the reaction chamber. As shown in FIG. 7, the chamber pressure increases by a greater amount during the second pressure rise regime 760P than during the first pressure rise regime 760P, indicating that a greater amount of second precursor was fed into the chamber. In some embodiments, where no inert gas is fed during the exposing 760 to the second precursor, the increase in pressure during the second pressure rise regime 760P may correspond to a partial pressure of the second precursor. The second pressure rise regime 760P may be followed by a second waiting pressure regime 670P. During the second waiting pressure regime 770P, the chamber pressure may be relatively constant and maintained at the second pressure. In some embodiments, where an inert gas is fed into the reaction chamber during the waiting 770, the chamber pressure may increase corresponding to the amount of inert gas fed into the chamber.

Referring to FIG. 7, after waiting 770 for the second time period, the reaction chamber may be pumped and/or purged 780. The pumping and/or purging 780 may correspond to a second pressure fall regime 780P. As shown in FIG. 7, during the second pressure fall regime 780P, the chamber pressure may fall from the second pressure back to the initial pressure, such that the vapor deposition cycle 730 may be repeated with a substantially similar chamber pressure regime. The chamber pressure falling back to the initial pressure corresponds to the gate valve being opened during the pumping and/or purging 780, allowing the gas within the chamber to be evacuated.

As described herein and throughout the specification, it will be appreciated that the substrate on which the conformal thin films according to embodiments can be implemented in a variety of substrates, including, but not limited to, a semiconductor substrate, a doped semiconductor substrate, which can be formed of an elemental Group IV material (e.g., Si, Ge, C or Sn) or an alloy formed of Group IV materials (e.g., SiGe, SiGeC, SiC, SiSn, SiSnC, GeSn, etc.); Group III-V compound semiconductor materials (e.g., GaAs, GaN, InAs, etc.) or an alloy formed of Group III-V materials; Group II-VI semiconductor materials (CdSe, CdS, ZnSe, etc.) or an alloy formed of Group II-VI materials.

According to certain embodiments, the substrate can also be implemented as a semiconductor on insulator, such as silicon on insulator (SOI), substrate. An SOI substrate typically includes a silicon-insulator-silicon structure in which the various structures described above are isolated from a support substrate using an insulator layer such as a buried SiO₂ layer. In addition, it will be appreciated that the various structures described herein can be at least partially formed in an epitaxial layer formed at or near a surface region.

Furthermore, the substrate can include a variety of structures formed thereon, e.g., diffusion regions, isolation regions, electrodes, vias and lines to name a few, on which any structure comprising the film according to embodiments may be formed, including topological features such as vias, cavities, holes or trenches having one or more semiconductor or dielectric surfaces. Thus, the surface on which a film according to embodiments is formed can include a semiconductor surface, e.g., a doped or undoped Si surface, and/or a dielectric surface, e.g., an interlayer dielectric (ILD) surface, a mask or a hard mask surface or a gate dielectric surface, to name a few, which can include an inorganic insulator, an oxide, a nitride, a high K dielectric, a low K dielectric, or carbon, to name a few dielectric materials.

As described herein and throughout the specification, a reactor chamber refers to any reaction chamber including a single wafer processing reaction chamber or a batch wafer processing reaction chamber that is suitably configured for vapor deposition. In a reactor chamber, the substrate may be placed on a suitable substrate holder, such as a susceptor or a carrier boat. The substrate may be directly heated by conduction through a heated susceptor, or indirectly heated by radiation from a radiation source such as a lamp or by convection through a heated chamber wall.

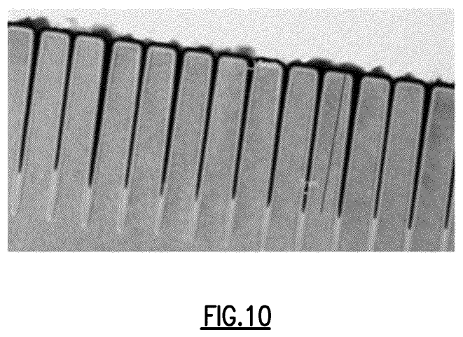

FIG. 10 illustrates an experimental transmission electron microscopy (TEM) image of a tungsten (W) film for gap fill of high aspect ratio trenches, formed according to an embodiment of the deposition techniques described herein. Without limitation, the illustrated thin film comprises W, according to embodiments. The example tungsten (W) film was deposited in a batch furnace. A nucleation stage was performed to grow a 20 Å film thickness of tungsten using WF₆ and B₂H₆. The bulk deposition stage was performed using WF₆ as the first precursor and H₂ as the second precursor. The example bulk W deposition reaction is provided as follows: WF6 (g)+3H2 (g)→W(s)+6HF (g).

FIG. 10 depicts the tungsten layer deposited with good gap fill within a trench pattern on the substrate, with the trench pattern having a 20:1 aspect ratio and an opening width of 15 nm. In some embodiments, when a liner or nucleation process is needed before a bulk layer, the liner may be formed in a separate non-batch reaction chamber, and the substrate may be transferred to a batch furnace for bulk film deposition using methods disclosed herein.

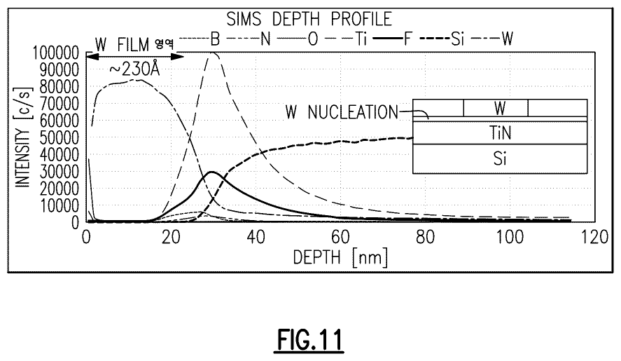

FIG. 11 illustrates a secondary ion mass spectrometry (SIMS) depth profile illustrating the presence of a W film of FIG. 10 having a thickness around 230 Å, the W film deposited on a TiN layer on a silicon substrate. FIG. 11 shows that there is a low fluorine content within the deposited tungsten film, leading to a high film quality from the low in-film impurity incorporated in the film. Without being limited by theory, this may because the higher ratio of reaction gas (H₂) introduced relative to the metal precursor gas (WF₆) produces a faster and more complete reaction, leaving minimal residual fluorine incorporated in the W film.

Table 1 below summarizes an experimental tungsten deposition process, including the growth rate per vapor deposition cycle for the tungsten film in various process conditions.

TABLE 1

| WF₆ Partial | H₂ Partial | Number of | Growth Rate per |
|---|---|---|---|
| Pressure (torr) | Pressure (torr) | Cycles | Cycle (Å/cycle) |
| 0.5 | 9 | 100 | 2.8 |
| 0.1 | 8.5 | 200 | 0.9 |
| 0.05 | 8.5 | 200 | 0.3 |

The growth rate at the center of the substrate using a WF₆ partial pressure of 0.5 torr was 2.8 Å/cycle. With a WF₆ partial pressure of 0.1 torr, the growth rate at the center was 0.9 Å/cycle, and with a WF₆ partial pressure of 0.05 torr, the growth rate at the center was 0.3 Å/cycle. Table 1 shows that the growth rate per cycle increases with a higher partial pressure, i.e., consumption of the metal precursor WF₆. Without being bound to any theory, this may be because higher partial pressure corresponds to a greater amount of precursor and tends to allow for the precursor to be more readily pre-positioned in the substrate structure, e.g., reach the bottom of the high aspect ratio, which also tends to improve step coverage. The grown tungsten films exhibited an electrical resistivity of around 25 μΩ·cm at a film thickness of 200 Å.

The inventors have found that the number of cycles to grow a film of a certain thickness may be much lower using the methods disclosed herein compared to using atomic layer deposition (ALD). For example, an experimental tungsten film of 200 Å thickness formed using ALD used around 1000 cycles. However, with reference to FIG. 9, the formation of a comparable tungsten film using the method disclosed herein used only around 220 cycles. Furthermore, the inventors have discovered that the amount of gas precursor used for the film formation may be much lower using the methods disclosed herein compared to ALD. The experimental tungsten film of 200 Å in thickness was formed using an ALD process by flowing around 8,333 cm³ of WF₆ gas precursor per wafer. However, with reference to FIG. 9, the formation of a comparable tungsten film using the method disclosed herein used only flowing around 62 cm³ of WF₆ gas precursor per wafer. Thus, the methods disclosed herein surprisingly used over 100 times less, i.e., less than 1%, of a gas precursor than would have been used in comparable ALD techniques. For example, the methods may use 132 times less of the gas precursor. In some embodiments, the methods disclosed herein may use less than 50%, 20%, 10%, less than 7%, less than 5%, less than 3%, less than 2%, less than 1%, or any value in a range defined by any of these values, of an amount of the first precursor used for forming a same thickness of a reference thin film having substantially the same composition as the thin film using a reference process with the same deposition conditions as forming the thin film except that the reference process evacuates the reaction chamber to remove a substantial amount of either or both of the first precursor or the second precursor during or between exposing the substrate to the first precursor and exposing the substrate to the second precursor.

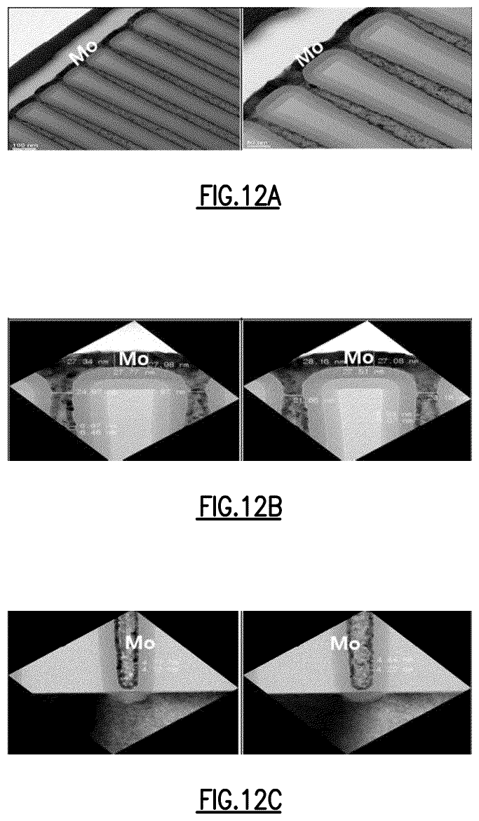

FIGS. 12A-12C illustrate experimental transmission electron microscopy (TEM) images of a conformal molybdenum (Mo) film for gap fill of high aspect ratio trenches, formed according to an embodiment of the deposition techniques described herein. The example deposition process was performed at a temperature of 550° C. The wait time of a first time period after the exposure to the first precursor was 120 seconds, and the wait time of a second time period after the exposure to the second precursor was 600 seconds. The Mo film is substantially conformal throughout the depth of the trench with good step coverage of greater than 60%, e.g., around 67%.

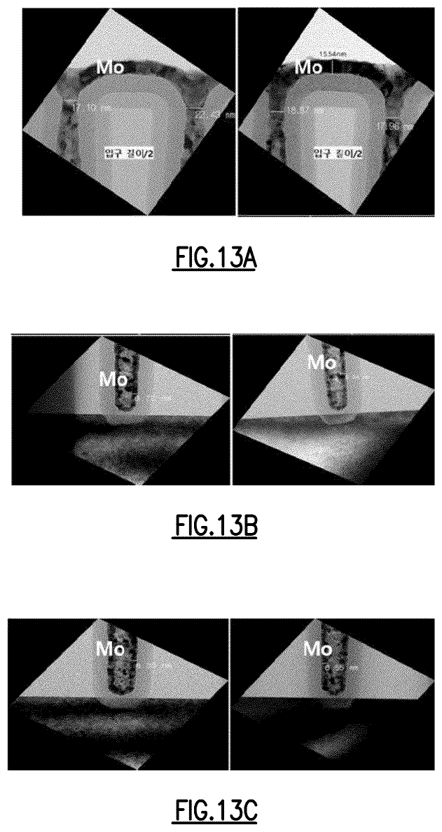

FIGS. 13A-13C illustrate experimental transmission electron microscopy (TEM) images of a conformal molybdenum (Mo) film for gap fill of high aspect ratio trenches, formed according to an embodiment of the deposition techniques described herein. The example deposition process was performed at a temperature of 550° C. The wait time of a first time period after the exposure to the first precursor was 600 seconds, and the wait time of a second time period after the exposure to the second precursor was 600 seconds. The Mo film is substantially conformal throughout the depth of the trench with excellent step coverage of greater than 90%, e.g., 96%, which is relatively higher to the step coverage of the Mo film shown in FIGS. 12A-12C. FIGS. 13A-13C shows that increasing the wait time of a first time period after the exposure to the first time precursor may result in a highly conformal film with a step coverage of greater than 70%, 80%, 90%, or 95%. Without being bound to any theory, this may be because waiting for a longer period of time after the exposure to the first precursor may allow the precursor to more uniformly distribute within the chamber and be readily pre-positioned within any high aspect ratio structures of the substrate before the second precursor is introduced into the reaction chamber.

In some embodiments, a longer wait time after either or both of exposing the substrate to the first precursor and exposing the substrate to the second precursor may improve the film quality and decrease resistivity. Table 2 below summarizes an experimental molybdenum nitride (MoN) deposition process using MoO₂Cl₂ and NH₃ as the first and second precursors, respectively. Table 2 demonstrates the sheet resistivity and the nonuniformity for the MoN film in various process conditions (e.g., wait times after exposure and without evacuating to substantially remove the precursor). It may be appreciated that, as the wait time increases after either of the first precursor or the second precursor, the sheet resistance of the MON film and the non-uniformity of the film may decrease. However, in some embodiments, it may be more advantageous to use a shorter wait time, depending on the application of the thin film.

TABLE 2

| Wait Time (sec) | Wait Time (sec) | Rs of MoN | Rs NU (%) |
|---|---|---|---|
| after MoO₂Cl₂ | after NH₃ | (Ω/sq) | of MoN |
| 10 | 10 | 6548 | 57.2 |
| 300 | 120 | 2452 | 14.3 |
| 600 | 120 | 2467 | 9.13 |
| 600 | 600 | 2038 | 5.6 |

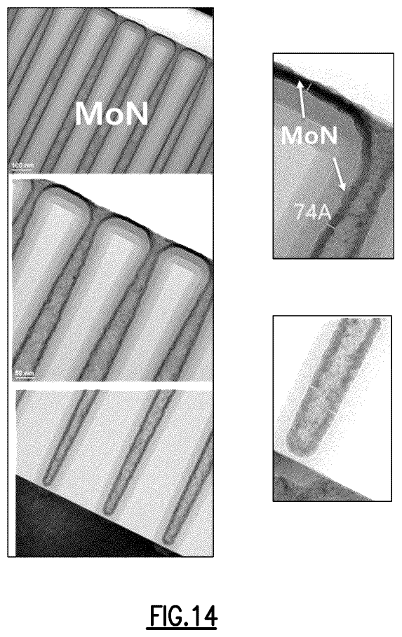

FIG. 14 illustrates experimental transmission electron microscopy (TEM) images of a conformal molybdenum nitride (MoN) film for lining high aspect ratio trenches, formed according to an embodiment of the deposition techniques described herein. The illustrated trenches have an opening width of 20 nm and an aspect ratio of 80. The example deposition process was performed at a temperature of 525° C. The first precursor in this example deposition process is MoO²Cl² provided in a canister at 100° C. and the second precursor is H₂. As shown in FIG. 14, the MON liner is extremely conformal with a step coverage greater than 95%, e.g., about 100%.

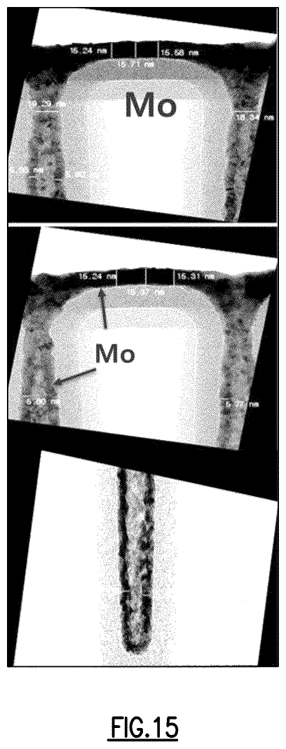

FIG. 15 illustrates experimental TEM images of a conformal molybdenum (Mo) film for lining high aspect ratio trenches, formed according to an embodiment of the deposition techniques described herein. The illustrated trenches have an opening width of about 20 nm and an aspect ratio of about 80. The example deposition process was performed at a temperature of 525° C. The first precursor in this example deposition process is MoO₂Cl₂ provided in a canister at 100° C. and the second precursor is H₂. As shown in FIG. 15, the Mo liner is extremely conformal with a step coverage greater than 95%, e.g., about 100%. The growth rate per cycle of the example deposition process is greater than 1 Å-6 Å per cycle. The resistivity of the example Mo film was measured at around 20 μΩ·cm, e.g., 20.8μΩ·cm, at a thickness of 120 Å. The example Mo film was deposited with a low surface roughness. As deposited, the example Mo film of FIG. 15 has a root-mean square surface roughness of around 0.65 nm at a thickness of around 100 Å. The Mo film thus has a root-mean square (RMS) roughness of about 6.5% of the average film thickness. The amount of precursor, e.g., MoO₂Cl₂, used for deposition may be less than about 0.1 g per wafer to form a film of 100 Å thickness.

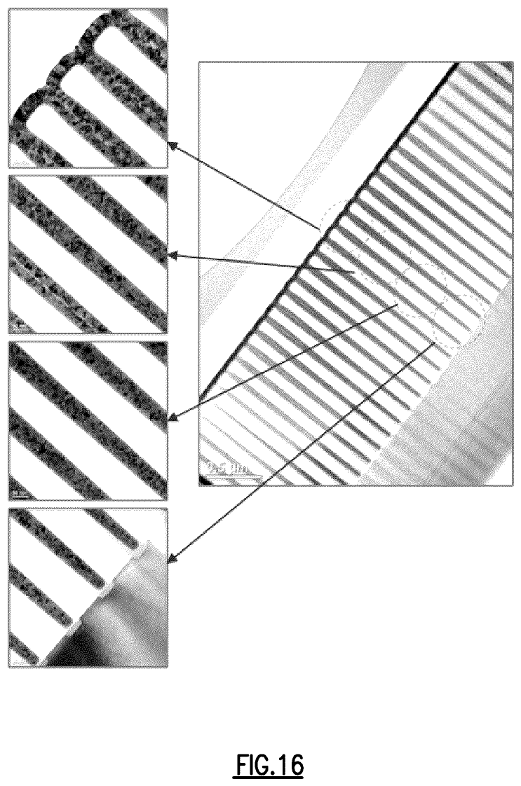

FIG. 16 illustrates experimental TEM images of a conformal molybdenum (Mo) film for gap fill of high aspect ratio trenches, formed according to an embodiment of the deposition techniques described herein. The illustrated trenches have an opening width of about 70 nm and an aspect ratio of about 20, e.g., 23. The example deposition process was performed at a temperature of 525° C. The first precursor in this example deposition process is MoO₂Cl₂ provided in a canister at 120° C. and the second precursor is H₂. As shown in FIG. 16, the Mo film exhibits good gap fill. The Mo film shown in FIG. 16 was deposited with a relatively high partial pressure of first precursor, e.g., MoO₂Cl₂, and thus has a high growth rate per cycle of 20 Å per cycle. Without being bound to any theory, this may be because higher partial pressure corresponds to a greater amount of precursor and tends to allow for the precursor to be more readily pre-positioned in the substrate structure, e.g., reach the bottom of the high aspect ratio, which also tends to improve step coverage and/or gap fill.

Forming 520 (FIG. 5A) of the film may comprise exposing a semiconductor substrate to 1-25 vapor deposition cycles, 25-50 vapor deposition cycles, 50-100 vapor deposition cycles, 100-200 vapor deposition cycles, 200-300 vapor deposition cycles, 300-400 vapor deposition cycles, 400-500 vapor deposition cycles, 500-600 vapor deposition cycles, 600-1000 vapor deposition cycles, 1000-2000 vapor deposition cycles, 2000-3000 vapor deposition cycles, 3000-4000 vapor deposition cycles, 4000-5000 vapor deposition cycles, or a value in a range defined by any of these values. For example, the number of vapor deposition cycles may be less than or equal to 200 cycles, or less than or equal to 100 cycles.

The inventors have discovered that the amount of the second precursor introduced into the reaction chamber during film formation can be several times greater than the amount of the first precursor introduced into the closed reaction chamber while achieving high step coverages as discussed herein. Advantageously, without being bound to any theory, a greater amount of second precursor causes a faster reaction with the first precursor due to increased collision frequency or higher flux. For example, a second volume of the second precursor introduced into the reaction chamber may be higher than a first volume of the first precursor introduced into the chamber by a factor greater than 2. This relatively high ratio of second volume to first volume may allow for a significant amount of the first volume of the first precursor to be used in film formation. In some cases, the volume of a precursor may be measured by multiplying a volumetric flow rate of the precursor by the exposure time of the precursor, assuming no inert gas is provided along with the precursor. A ratio between the second volume of the second precursor (FIG. 5B) and the first volume of the first precursor (FIG. 5B) may be about 2-3, 3-5, 5-10, 10-15, 15-20, 20-50, 50-100, 100-10,000 or a ratio in a range defined by any of these values. It will be appreciated that the ratio will vary in different embodiments, depending on the chemical composition of the precursors used and the thin film to be produced. The percentage of the first volume of the first precursor that reacts to form the thin film in a vapor deposition cycle (FIG. 5B) may be about 10%, 20%, 30%, 40%, 50%, 60%, 70%, 80%, 90%, 95%, 100%, or an amount in a range defined by any of these values.

It may be appreciated that, when the reaction chamber remains closed throughout a majority of the vapor deposition cycle, a partial pressure ratio between the second precursor and the first precursor (P_{B}/P_{A}) may be based on a ratio between the respective molar amounts (X_{B}/X_{A}) of the reactants used in a deposition cycle. For example, the P_{B}/P_{A} for a W deposition reaction according to the equation WF₆ (g)+3H₂ (g)→W(s)+6HF (g) may be, e.g., about 3. Analogously, the P_{B}/P_{A} for a Mo deposition reaction according to the equation 2MoCl₅ (g)+5H₂ (g)→2Mo(s)+10HCl (g) may be, e.g., about 2.5. Analogously, the P_{B}/P_{A} for Mo deposition reaction according to the equation MoO₂Cl₂ (g)+3H₂→Mo(s)+2HCl (g)+2H₂O (g) may be about 3. It will be appreciated that the P_{B}/P_{A} employed may depart from the X_{B}/X_{A} of the reaction equation. For example, the PR/P_{A} may be greater than 0.2, 0.4, 0.6 0.8, 1.0, 1.2, 1.4, 1.6, 1.8, 2.0 times X_{B}/X_{A} or have a value in a range defined by any of these values. In some embodiments, a ratio of the partial pressure of the second precursor to a partial pressure of the first precursor after exposing the substrate to the second precursor may be about 2-3, 3-5, 5-10, 10-15, 15-20, 20-50, 50-100, 100-10,000 or a ratio in a range defined by any of these values.

The inventors have discovered that higher P_{B}/P_{A} can advantageously lead to faster reaction and higher film quality with reduced impurity (e.g., F, Cl, O) incorporated in the film. The inventors discovered that, if such high ratios are employed in a comparable CVD process, step coverage may degrade because, without being bound to any theory, high reaction rate can make the deposition stay in mass transfer-controlled regime. On the contrary, according to embodiments of disclosure, because the first precursor is pre-positioned (adsorbed) inside the semiconductor device structure before the second precursor is introduced, the resulting step coverage may not be affected as much by the higher P_{B}/P_{A} or high growth rate.

According to various embodiments, non-limiting examples of the inert gas for purging may include nitrogen N₂ or a noble gas such as Ar or He. Furthermore, either of the first precursor or the second precursor may be fed into the reaction chamber along with some volume of an inert gas. The inert gas may also be fed into the reaction chamber during either of the waiting periods after introducing either of the first precursor and/or the second precursor.

The partial pressure of the first precursor (FIG. 5B) in exposing 540 may be greater than about 10 mTorr, 100 mTorr, 200 mTorr, 500 mTorr, 1 Torr, 2 Torr, 5 Torr, 10 Torr or a value in a range defined by any of these values. The partial pressure of the second precursor (FIG. 5B) in exposing 560 with the existing first precursor may be greater than about 10 mTorr, 50 mTorr, 100 mTorr, 200 mTorr, 500 mTorr, 1 Torr, 2 Torr, 5 Torr, 10 Torr, 20 Torr, 50 Torr, 100 Torr, 200 Torr, 700 Torr or a value in a range defined by any of these values. The chamber pressure after pumping and/or purging 570 (FIG. 5B) may be less than 10 Torr, 1 Torr, 100 mTorr or a value in a range defined by any of these values.

Various technical advantages and benefits described herein can be realized when the thin film is formed at a substrate temperature of 15° C., 100° C., 200° C., 300° C., 400° C., 500° C., 600° C., 700° C., 800° C. or a temperature in a range defined by any of these values, for instance about 500-600° C., according to embodiments. Keeping the temperature the same during the exposure to the first precursor and second precursor may be advantageous for throughput an ease of process control, as temperature adjustments during process may take long time.

In various embodiments, the optional first time period of waiting 550 (FIG. 5B) may be about or greater than 1 second, 3 seconds, 5 seconds, 10 seconds, 20 seconds, 30 seconds, 1 minute, 2 minutes, 5 minutes, 10 minutes, 20 minutes, 30 minutes, 40 minutes, 50 minutes, 60 minutes, or a time defined by a range of any of these values. In some embodiments, the optional second time period of waiting 570 (FIG. 5B) may be about or greater than 1 second, 3 seconds, 5 seconds, 10 seconds, 20 seconds, 30 seconds, 1 minute, 2 minutes, 5 minutes, 10 minutes, 20 minutes, 30 minutes, 40 minutes, 50 minutes, 60 minutes, or a time defined by a range of any of these values.

As deposited, a thin film comprising, e.g., W or Mo, formed according to the methods described herein and having a thickness of about 200 Å can have an electrical resistivity of <10-50 μΩ·cm, or a value in a range defined by any of these values, for instance less than about 50μΩ·cm.

In addition to reduced precursor composition, the thin film formed according to the methods disclosed herein has high conformality when deposited in high aspect ratio structures. A semiconductor substrate may comprise an opening or other structure having a high aspect ratio. One measure of conformality in the context of high aspect ratio structures is referred to herein as step coverage. A high aspect ratio structure may be, e.g., a via, a hole, a trench, a cavity, multiple lateral cavities in a stacked structure (such as 3D NAND word line and 3D DRAM word line), or a similar structure. By way of an illustrative example, FIGS. 1-3 schematically illustrates a semiconductor structure having an example high aspect ratio structure formed therein, to illustrate some example metrics of defining and/or measuring conformality of thin films formed on high aspect ratio structures. As described herein, a high aspect ratio structure has an aspect ratio, e.g., a ratio defined as a depth or height (H) divided by a width (W) at the opening region of the high aspect ratio structure, that exceeds 1. In the illustrated example, the high aspect ratio structure is a via formed through a dielectric layer, e.g., an intermetal dielectric (ILD) layer, formed on a semiconductor substrate, such that a bottom surface of the high aspect ratio structure exposes the underlying semiconductor. The deposited film can coat different surfaces of the high aspect ratio structure with different thicknesses. As described herein, one metric for defining or measuring the conformality of a thin film formed in a high aspect ratio is referred to as step coverage. A step coverage may be defined as a ratio between a thickness of a thin film at a lower or bottom region of a high aspect ratio structure and a thickness of the thin film at an upper or top region of the high aspect ratio structure. The upper or top region may be a region of the high aspect ratio structure at a relatively small depth at, e.g., 0-10% or 0-25% of the H measured from the top of the opening. The lower or bottom region may be a region of the high aspect ratio structure at a relatively high depth at, e.g., 90-100% or 75-100% of the H measured from the top of the opening. In some high aspect ratio structures, a step coverage may be defined or measured by a ratio of thicknesses of the thin film formed at a bottom surface to the thin film formed at upper or top sidewall surfaces of the high aspect ratio structure. However, it will be appreciated that some high aspect ratio structures may not have a well-defined bottom surface or a bottom surface having small radius of curvature. In these structures, a step coverage may be more consistently defined or measured by a ratio of thicknesses of the thin film formed at a lower or bottom sidewall surface to the thin film formed at an upper or top sidewall surfaces of the high aspect ratio structure.

As described above, the thin formed according to the methods disclosed herein results in lower precursor consumption and high growth rate and throughput, while also providing high conformality in high aspect ratio structures. According to various embodiments, high aspect ratio structures having an aspect ratio exceeding 1, 2, 5, 10, 20, 50, 100, 200, 1000 or a value in a range defined by any of these values may be conformally coated with films according to embodiments with a step coverage as defined herein that exceeds 10%, 20%, 30%, 40%, 50%, 60%, 70%, 80%, 90%, 95%, or has a value in a range defined by any of these values. Additionally, high aspect ratio structures having a width of 5 nm, 10 nm, 15 nm, 20 nm, 25 nm, 30 nm, 50 nm, 100 nm, 200 nm, 500 nm or a width in a range defined by any of these values may exhibit gap fill by the films deposited according to embodiments herein.

The inventors have found that, advantageously, when a thin film is formed according to embodiments disclosed herein, the surface roughness can also be reduced compared to other films formed using other techniques, e.g., CVD or PVD. The reduced surface roughness is particularly advantageous compared to other materials or techniques when the surface on which the film is deposited comprises a nonmetallic surface, e.g., a dielectric surface and/or a semiconductor surface exposed by an opening such as a via or a trench. As deposited according to methods disclosed herein, the films can have a root-mean square (RMS) surface roughness of 0.5%, 1%, 1.5%, 2%, 2.5%, 3%, 3.5%, 4%, 4.5%, 5%, 5.5%, 6%, 6.5%, 7%, 7.5%, 8%, 8.5%, 9%, 9.5%, and 10%, on the basis of an average thickness of the film, or a value in a range defined by any of these values or a lower value. Alternatively, as-deposited, the films having a thickness of around 9-12 nm can have a root-mean square (RMS) surface roughness value that is less than 0.8 nm, 0.7 nm, 0.6 nm, 0.5 nm, 0.4 nm, 0.3 nm, 0.2 nm, 0.1 nm, or a value in a range defined by any of these values or a lower value. The reduced RMS roughness can in turn improve the conformality of the deposited films.

A growth rate of the film deposited according to methods disclosed herein may be at least <1 Å/cycle, 1 Å/cycle, 2 Å/cycle, 5 Å/cycle, 10 Å/cycle, 20 Å/cycle, 50 Å/cycle, 100 Å/cycle, or a growth rate in a range defined by any of these values. In some embodiments, the growth rate may comprise at least 0.5 Å/cycle. The ratio of a total volume of gas precursor used according to methods disclosed herein to form a film with a thickness and a total volume of gas precursor used for an ALD process to form a film with the same thickness under the same process conditions may be about 1:3-1:5, 1:5-1:10, 1:10-1:15, 1:15-1:20, 1:20-1:50, 1:50-1:100, 1:100-1:200, 1:200-1:300, 1:300-1:500, or a ratio in a range defined by any of these values.

According to various embodiments, the film deposited with the methods disclosed herein can comprise a metal. For example, the film may comprise any one of W, Mo, Co, Cu, Ru, or Al. In some embodiments, the film deposited with the methods disclosed herein can comprise a metal nitride. For example, the film may comprise any one of TiN, VN, MON, TaN, WN, TiSiN, TiAlN, ZrN, or HfN. In some embodiments, the film deposited with the methods disclosed herein can comprise a metal oxide. For example, the film may comprise any one of HfO₂, ZrO₂, MoO₂. TiO₂, Al₂O₃, or NbO₂. In some embodiments, the film deposited with the methods disclosed herein can comprise silicon. For example, the film may comprise any one of Si, SiN, SiOCN, SiO₂, or Si₃N₄.

According to various embodiments, the first precursor may comprise a gas selected from the group consisting of: WF₆, WCl₅, MoO₂Cl₂, MoCl₅, MoF₆, TiCl₄, VCl₄, HfCl₄, ZrCl₄, SiH₄, Si₂H₆, BCl₃, Si₂Cl₂H₂. According to various embodiments, the first precursor may comprise a gas comprising any one of Si, Mo, Ti, W, Co, V, Zr, Hf, Ta, Cu, Al, Pt, Ir, or Ru, which may be bonded to a halogen such as chlorine, fluorine, or iodine, or an organic gas comprising carbon and hydrogen, or carbon, hydrogen, and nitrogen. In some embodiments, the first precursor may comprise a metal organic precursor. For example, the first precursor may comprise a metal organic precursor comprising any one of Ru, Co, Cu, Al, Mo, W, Hf, or Zr ions. According to various embodiments, the second precursor may comprise a gas selected from the group consisting of: H₂, O₂, H₂O, O₃, NH₃, and B₂H₆.

### Applications

The thin films formed according to various embodiments disclosed herein can be used in a variety of applications, particularly where the substrate comprises a relatively high aspect ratio structure and/or a non-metal surface that can benefit from various advantageous characteristics of the film as disclosed herein. Example applications include deposition a via, a hole, a trench, a cavity, multiple lateral cavities in a stacked structure (such as 3D NAND word line and 3D DRAM word line), or a similar structure having an aspect ratio, e.g., a ratio defined as a depth divided by a top width, that exceeds 1, 2, 5, 10, 20, 50, 100, 200, 1000, or a value in a range defined by any of these values. Additional example applications may include metal fill, oxide fill, capacitor electrodes, high K dielectric layers for capacitors, barrier metals, SiN, SiOCN, etc.

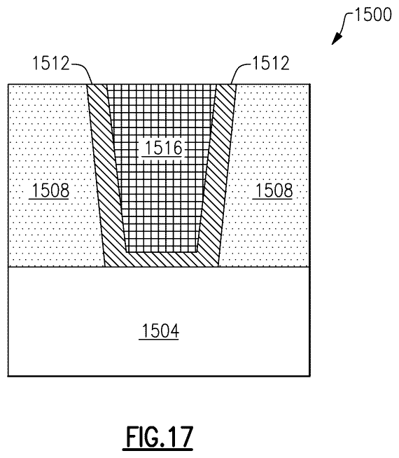

By way of example, FIG. 17 schematically illustrates an application in the context of a diffusion barrier for a contact structure, e.g., a source or drain contact, formed on an active semiconductor substrate region that may be heavily doped. A portion of a semiconductor device 1500 is illustrated, which includes a substrate 1504 on which a dielectric layer 1508, e.g., an interlayer or intermetal dielectric (ILD) layer comprising a dielectric material such as an oxide or nitride is formed. In order to form contacts to various regions of the substrate 1504, including various doped regions, e.g., source and drain regions, a via or a trench may be formed through the dielectric layer 1508. The via or the trench may expose various non-metal surfaces, e.g., an exposed bottom surface comprising a substrate surface, e.g., a silicon substrate surface, as well as dielectric sidewalls of the vias. The bottom and side surfaces of the via can be conformally coated with a barrier layer, e.g., a MON layer, formed according to various embodiments described herein. A conformal first portion may first be formed directly on inner surfaces of the via, according various embodiments disclosed herein. Thereafter, the lined via may be filled with a metal, e.g., W, Mo, Al or Cu, to form a contact plug 1516. For example, the via may be filled with tungsten or molybdenum, according to various embodiments disclosed herein, using, e.g., WF₆ or MoO₂Cl₂.

The barrier layer 1512 formed according to embodiments can be advantageous for various reasons. In particular, due to the conformal nature of the barrier layer 1512 formed according to various embodiments disclosed herein, the propensity for a pinching off during the subsequent metal fill process may be substantially reduced. In addition, as described above, the barrier layer 1512 can provide effective hindrance of material transport thereacross, e.g., dopant (B, P) out-diffusion from the substrate 1504, as well as in-diffusion of reactants, etchants and metals (e.g., F, Cl, W or Cu) from the contact plug formation process. The barrier effect may be enhanced by reduced surface roughness and increased step coverage. Furthermore, as described above, keeping the gate valve closed and allowing the precursor to uniformly spread within a reaction chamber may increase a growth rate per cycle and greatly reduce the overall precursor used for formation of the barrier layer 1512. Furthermore, due to the reduced film roughness, a relatively thinner barrier layer 1512 may be formed while still accomplishing its desired barrier function, leading to further reduction in contact resistance.

### Example Embodiments

1. A method of forming a thin film, the method comprising:
   forming a thin film on a substrate by exposing the substrate to one or more vapor deposition cycles in a reaction chamber, wherein exposing the substrate to each vapor deposition cycle comprises:
   exposing the substrate to a first volume of a first precursor, followed by exposing the substrate to a second volume of a second precursor,
   wherein exposing the substrate to the first and second volumes is carried out without evacuating to substantially remove the first and second volumes during and between exposing the substrate to the first and second volumes.
2. A method of forming a thin film, the method comprising:
   forming a thin film on a substrate by exposing the substrate to one or more vapor deposition cycles in a reaction chamber, wherein exposing the substrate to each vapor deposition cycle comprises:
   exposing the substrate to a first volume of a first precursor; and
   exposing the substrate to a second volume of a second precursor,
   wherein a ratio of the second volume to the first volume is at least 5, and
   wherein exposing the substrate to the first and second volumes is carried out without evacuating to substantially remove the first and second volumes during and between exposing the substrate to the first and second volumes.
3. A method of forming a thin film, the method comprising:
   forming a thin film on a substrate by exposing the substrate to one or more vapor deposition cycles in a reaction chamber comprising a gate valve configured to gate a vacuum pump, wherein exposing the substrate to each vapor deposition cycle comprises:
   exposing the substrate to a first volume of a first precursor with the gate valve closed; and
   exposing the substrate to a second volume of a second precursor with the gate valve closed,
   wherein exposing the substrate to the first and second volumes is carried out without opening the gate valve to substantially remove the first and second volumes during and between exposing the substrate to the first and second volumes.
4. The method of any one of the Embodiments 1 and 3, wherein a ratio of the second volume to the first volume is at least 5.
5. The method of any one of Embodiments 1 and 2, wherein the reaction chamber comprises a gate valve, and wherein exposing the substrate to the second volume follows exposing the substrate to the first volume without opening a gate valve.
6. The method of any one of Embodiments 2 and 3, wherein exposing the substrate to the first precursor is followed by exposing the substrate to the second precursor.
7. The method of any one of the above Embodiments, wherein exposing the substrate to the first volume comprises flowing the first precursor into the reaction chamber and exposing the substrate to the second volume comprises flowing the second precursor into the reaction chamber, wherein flowing the first precursor and flowing the second precursor do not temporally overlap with each other.
8. The method of any one of the above Embodiments, wherein exposing the substrate to the first precursor is immediately followed by exposing the substrate to the second precursor without an intervening exposure to any precursor.
9. The method of any one of the above Embodiments, wherein exposing the substrate without the intervening evacuation process includes not subjecting the reaction chamber to substantial pumping.
10. The method of any one of the above Embodiments, further comprising waiting for a time period of at least 1 second after exposing the substrate to the first precursor and before exposing the substrate to the second precursor.
11. The method of any one of the above Embodiments, wherein the first precursor comprises a gas selected from the group consisting of: WF₆, WCl₅, MoO₂Cl₂, MoCl₅, MoF₆, TiCl₄, VCl₄, HfCl₄, ZrCl₄, SiH₄, Si₂H₆, BCl₃, Si₂Cl₂H₂.
12. The method of any one of the above Embodiments, wherein the first precursor comprises a metal organic precursor comprising any one of Ru, Co, Cu, Al, Mo, W, Hf, Si, or Zr ions.
13. The method of any one of the above Embodiments, wherein the second precursor comprises a gas selected from the group consisting of: H₂, O₂, H₂O, O₃, NH₃, and B₂H₆.
14. The method of any one of the above Embodiments, wherein exposing the substrate to the first precursor or exposing the substrate to the second precursor comprises flowing an inert gas along with a respective one of the first precursor or the second precursor.
15. The method of any one of the above Embodiments, wherein the reaction chamber comprises a batch furnace configured to form the thin film on a plurality of substrates.
16. The method of any one of the above Embodiments, wherein the reaction chamber comprises a batch furnace configured to form the thin film on 2 to 200 vertically stacked substrates.
17. The method of any one of the above Embodiments, wherein the reaction chamber comprises a heating source around the periphery of the reaction chamber.
18. The method of any one of the above Embodiments, wherein exposing the substrate to the one or move vapor deposition cycles is performed at a substrate temperature of 15° C. to 800° C.
19. The method of any one of the above Embodiments, wherein the thin film comprises a metal.
20. The method of any one of the above Embodiments, wherein the thin film comprises any one of W, Mo, Co, Cu, Ru, or Al.
21. The method of any one of the above Embodiments, wherein the thin film comprises a metal nitride.
22. The method of Embodiment 21, wherein the metal nitride comprises any one of TiN, VN, TaN, WN, MON, TiSiN, TiAlN, ZrN, or HfN.
23. The method of any one of the above Embodiments, wherein the thin film comprises a metal oxide.
24. The method of Embodiment 23, wherein the thin film comprises metal oxide comprises any one of HfO₂, ZrO₂, MoO₂. TiO₂, Al₂O₃, or NbO₂.
25. The method of any one of the above Embodiments, wherein the thin film comprises any one of Si, SiO₂, or Si₃N₄.
26. The method of any one of the above Embodiments, wherein the one or more vapor deposition cycles is less than or equal to 5,000 vapor deposition cycles.
27. The method of any one of the above Embodiments, wherein the one or more vapor deposition cycles is less than or equal to 1,000 vapor deposition cycles.
28. The method of any one of the above Embodiments, wherein a total pressure in the reaction chamber is less than 760 torr throughout the vapor deposition cycle.
29. The method of any one of the above Embodiments, wherein each vapor deposition cycle further comprises pumping and/or purging a remaining volume of the first precursor, the second precursor, and reaction by-product gases at the end of the vapor deposition cycle.
30. The method of any one of the above Embodiments, wherein the pressure in the reaction chamber immediately after purging is less than 100 mTorr.
31. The method of Embodiment 15, wherein a volume of the reaction chamber per substrate in the batch furnace is less than 10 L.
32. The method of Embodiment 15, wherein a chamber cavity volume per substrate in the batch furnace is less than 2 L.
33. The method of any one of the above Embodiments, further comprising forming an initial layer on the substrate prior to forming the thin film.
34. The method of Embodiment 33, wherein the initial layer comprises any one of W, Mo, WN, MON, TiN, TaN, VN, or TiSiN.
35. The method of Embodiment 33, wherein the initial layer is formed in a separate reaction chamber.
36. The method of any one of the above Embodiments, wherein a plurality of layers of the thin film are formed during the vapor deposition cycle.
37. The method of any one of the above Embodiments, wherein the thin film has a step coverage of at least 50%.
38. The method of any one of the above Embodiments, wherein exposing the substrate to the first precursor comprises exposing at a pressure in the reaction chamber of 10 mTorr to 10 torr.
39. The method of any one of the above Embodiments, wherein the substrate comprises an opening.
40. The method of Embodiment 39, wherein the opening has an aspect ratio of at least 10.
41. The method of any one of the above Embodiments, further comprising waiting for a time period of at least 1 second after exposing the substrate to the second precursor.
42. The method of any one of the above Embodiments, wherein the first precursor and the second precursor react to form the thin film on a surface of the substrate.
43. The method of Embodiment 42, wherein at least 10% of the first volume of the first precursor reacts to form the thin film.
44. The method of any one of the above Embodiments, wherein a growth rate of the thin film comprises at least 0.5 Å/cycle.
45. The method of any one of the above Embodiments, wherein the batch furnace is configured to form the thin film on 2 to 200 substrates.
46. The method of any one of the above Embodiments, wherein a growth rate per vapor deposition cycle of the thin film is at least about 1 Å/cycle.
47. The method of any one of the above Embodiments, wherein the substrate comprises a plurality of openings having an aspect ratio exceeding 5, and a step coverage of the thin film is at least 60%.
48. The method of any one of the above Embodiments, wherein a total volume of the first precursor used for forming a thickness of the thin film is less than 50% of a volume of the first precursor used for forming a same thickness of a reference thin film having substantially the same composition as the thin film using a reference process with the same deposition conditions as forming the thin film except that the reference process evacuates the reaction chamber to remove a substantial amount of either or both of the first precursor or the second precursor during or between exposing the substrate to the first precursor and exposing the substrate to the second precursor.
49. The method of any one of the above Embodiments, wherein a ratio of a partial pressure of the second precursor to a partial pressure of the first precursor within the reaction chamber is at least 5.
50. The method of any one of the above Embodiments, wherein the first precursor comprises atoms of any one of Si, Mo, Ti, W, Co, V, Zr, Hf, Ta, Cu, Al, Pt, Ir, or Ru.
51. The method of Embodiment 50, wherein the atoms of the first precursor are bonded to a halogen or an organic compound.

Although the present invention has been described herein with reference to the specific embodiments, these embodiments do not serve to limit the invention and are set forth for illustrative purposes. It will be apparent to those skilled in the art that modifications and improvements can be made without departing from the spirit and scope of the invention.

Such simple modifications and improvements of the various embodiments disclosed herein are within the scope of the disclosed technology, and the specific scope of the disclosed technology will be additionally defined by the appended claims.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

1. A method of forming a thin film, the method comprising:
forming a thin film on a substrate by exposing the substrate to one or more vapor deposition cycles in a reaction chamber, wherein exposing the substrate to each vapor deposition cycle comprises:
exposing the substrate to a first precursor, followed by exposing the substrate to a second precursor,
wherein exposing the substrate to the first precursor and the second precursor is carried out without evacuating the reaction chamber to remove a substantial amount of either of the first precursor or the second precursor during and between exposing the substrate to the first precursor and exposing the substrate to the second precursor.

2. The method of claim 1, wherein exposing the substrate to the first precursor comprises flowing the first precursor into the reaction chamber and exposing the substrate to the second precursor comprises flowing the second precursor into the reaction chamber, wherein flowing the first precursor and flowing the second precursor do not temporally overlap with each other.

3. The method of claim 1, wherein exposing the substrate to the first precursor is followed by exposing the substrate to the second precursor without an intervening exposure to any precursor.

4. The method of claim 1, wherein exposing the substrate to each of the first precursor and the second precursor without evacuating includes not subjecting the reaction chamber to any substantial pumping.

5. The method of claim 1, wherein one or both of exposing the substrate to the first precursor and exposing the substrate to the second precursor is followed by waiting for a respective time period of about 1 second to about 1 hour without introducing any precursor into the reaction chamber and without evacuating to remove a substantial amount of either of the first precursor or the second precursor.

6. The method of claim 5, wherein exposing the substrate to the first precursor is followed by waiting for a first time period of about 3 seconds to about 600 seconds before exposing the substrate to the second precursor.

7. The method of claim 5, wherein exposing the substrate to the second precursor is followed by waiting for a second time period of about 3 seconds to about 600 seconds.

8. The method of claim 1, wherein each vapor deposition cycle further comprises evacuating the reaction chamber after exposing the substrate to the second precursor.

9. The method of claim 1, wherein the reaction chamber comprises a gate valve configured to gate a vacuum pump of the reaction chamber, wherein the gate valve remains closed during and between exposing the substrate to the first precursor and exposing the substrate to the second precursor.

10. The method of claim 1, wherein a ratio of a second volume of the second precursor introduced into the reaction chamber to a first volume of the first precursor introduced into the reaction chamber during each vapor deposition cycle is greater than 3.

11. The method of claim 1, wherein a growth rate per vapor deposition cycle of the thin film is at least about 0.3 Å/cycle.

12. The method of claim 1, wherein a total volume of the first precursor used for forming a thickness of the thin film is less than 10% of a volume of the first precursor used for forming a same thickness of a reference thin film having substantially the same composition as the thin film using a reference process with the same deposition conditions as forming the thin film except that the reference process evacuates the reaction chamber to remove a substantial amount of either or both of the first precursor or the second precursor during or between exposing the substrate to the first precursor and exposing the substrate to the second precursor.

13. The method of claim 1, wherein one or both of exposing the substrate to the first precursor and exposing the substrate to the second precursor includes flowing an inert gas into the reaction chamber along with a respective one of the first and second precursors.

14.-34. (canceled)

35. A method of forming a thin film, the method comprising:
forming a thin film on a substrate by exposing the substrate to one or more vapor deposition cycles in a reaction chamber, wherein exposing the substrate to each vapor deposition cycle comprises:
exposing the substrate to a first precursor, followed by exposing the substrate to a second precursor,
wherein exposing the substrate to the first precursor and the second precursor is carried out without evacuating the reaction chamber to remove a substantial amount of either of the first precursor or the second precursor during exposing the substrate to the first precursor and the second precursor, and
wherein after exposing the substrate to one or both of the first precursor and the second precursor without evacuating the reaction chamber, evacuating the reaction chamber to substantially remove a respective one or both of the first precursor and the second precursor.

36. The method of claim 35, wherein one or both of exposing the substrate to the first precursor and exposing the substrate to the second precursor is followed by waiting for a respective time period of about 1 second to about 1 hour without introducing any precursor into the reaction chamber and without evacuating to remove a substantial amount of either of the first precursor or the second precursor.

37. The method of claim 36, wherein exposing the substrate to the first precursor is followed by waiting for a first time period of about 3 seconds to about 600 seconds before exposing the substrate to the second precursor.

38. The method of claim 36, wherein exposing the substrate to the second precursor is followed by waiting for a second time period of about 3 seconds to about 600 seconds.

39. The method of claim 35, wherein after exposing the substrate to each of the first precursor and the second precursor without evacuating the reaction chamber, evacuating the reaction chamber to substantially remove a respective one of the first precursor and the second precursor.

40. The method of claim 35, wherein the reaction chamber comprises a gate valve configured to gate a vacuum pump of the reaction chamber, wherein the gate valve remains closed during exposing the substrate to each of the first precursor and the second precursor.

41. The method of claim 35, wherein a ratio of a second volume of the second precursor introduced into the reaction chamber to a first volume of the first precursor introduced into the reaction chamber during each vapor deposition cycle is greater than 3.

42. The method of claim 35, wherein one or both of exposing the substrate to the first precursor and exposing the substrate to the second precursor includes flowing an inert gas into the reaction chamber along with a respective one of one of the first and second precursors.
